(19) United States
(12) Patent Application Publication
(10) Pub. No.: US 2025/0036835 A1
(43) Pub. Date: Jan. 30, 2025

(54) Fabrication Process Design Using Bayesian Optimization with Active Constraint Learning

(71) Applicant: Northeastern University, Boston, MA (US)

(72) Inventors: Swastik KAR, Belmont, MA (US); Xiaoning JIN, Boston, MA (US); Guoyan LI, Medford, MA (US); Yujia WANG, Boston, MA (US)

(21) Appl. No.: 18/776,170

(22) Filed: Jul. 17, 2024

Related U.S. Application Data
(60) Provisional application No. 63/527,328, filed on Jul. 17, 2023.

(51) Int. Cl. G06F 30/27; G06F 18/2415

(52) U.S. Cl. CPC G06F 30/27; G06F 18/24155

(57) ABSTRACT

Provided herein are methods and systems for a computer implemented method for designing and optimizing a fabrication process characterized by one or more process parameters. The outcome of the fabrication process is characterized by a quality metric used to optimize the fabrication process. The method uses a classification model in conjunction with a regression model, both using artificial intelligence and trained using experimental results, to iteratively recommend process parameter values for performing real world fabrication experiments. The experimental results are used to continuously train the models. The outcome is a set of process parameters that yield an optimal fabrication process with less time and effort than using conventional design of experiment methods.

### CROSS REFERENCE TO RELATED APPLICATIONS

This application claims the priority of U.S. Provisional Application No. 63/527,328 filed Jul. 17, 2023 and entitled “Synthesis of 2D Materials Optimized by Machine Learning”, the whole of which is hereby incorporated by reference.

### STATEMENT REGARDING FEDERALLY SPONSORED RESEARCH OR DEVELOPMENT

This invention was made with government support under Grant No. 1351424 awarded by the National Science Foundation. The government has certain rights in the invention.

### BACKGROUND

The first demonstration of synthesis using chemical vapor deposition (CVD) is often treated as a watershed moment in the developmental phase of any two-dimensional (2D) material [1-3]. CVD synthesis opens up new avenues of materials science and engineering research and allows for direct growth of doped, alloyed [4], and other complex hybrid [5] and heterogeneous structures [6] with new physics and functionalities. It also provides a low-cost low-risk pathway from initial demonstration of applications to industrial-level scalable, uniform production [7]. Despite its appeal, the transition towards higher quality for graphene, transition metal dichalcogenides (TMDs) and other 2D materials using CVD synthesis has historically required years of optimization. CVD synthesis involves a complex interplay of thermodynamics and chemical kinetics at the growth front at the atomic scale under the dynamic arrival of reactants and removal of products. Most experimentalists attempt to reach ideal synthesis conditions within the Design of Experiment (DoE) space, utilizing external control of variables such as temperature, pressure, materials fluxes, duration of growth, ramp rates, positions of source and target materials and other macroscopic parameters. The resulting conditions at the growth front at the atomic scale vary from those intended by the externally set parameters owing to their complex, nonlinear relationships, parameter interdependencies, and fluctuations arising from carrier gas flow.

Recognizing patterns that can systematically guide experiments towards high quality in the complex multi-dimensional DoE space remains a formidable challenge. As a result, maturing the development of 2D materials from early discovery stages remains an art, relying heavily on years of experience and time-consuming, expensive trial and error efforts. This problem is not unique to 2D materials, and hence a method for accelerating the CVD synthesis maturing timeframe for a 2D material, which is also transferrable to other materials and types of furnaces or reactors, would result in a tremendous saving of time, effort, and costs for materials in their early stages of development.

### SUMMARY

The present technology provides a computer implemented method for designing a fabrication process by determining one or more optimal process parameters using a minimum number of experimental trials. The fabrication process is characterized by one or more process parameters including process steps, starting materials, chemical reactants, fabrication or assembly conditions, and the like, and the selection of values for these parameters can affect the outcome of the fabrication process. If a trial and error, real world experimental process were used for optimization, dozens or even hundreds of trials might be required, involving a large investment of time, effort, and materials. In the present method, the outcome of the fabrication process is characterized by one or more quality metrics or criteria by which the relative success of the fabrication process can be assessed. A range or threshold of desired values of one or more such quality metrics can be provided by a user at the outset of the optimization method, and the endpoint of the method can be a set of process parameter values that produce an outcome within the desired range of the quality metrics specified at the outset.

An aspect of the technology is a computer-implemented method for optimizing a fabrication process. The method includes the following steps:
receiving process data, wherein the process data includes a set of data points, each data point representing a set of one or more process parameters for the fabrication process and corresponding results for the fabrication process, wherein the set of data points are sampled from a defined design space of process parameter values, and wherein the results include a success indicator representing a successful fabrication and a quality metric representing a measurement of the fabrication process for each set of process parameters;
determining a feasible region from the process data and using a classification model, wherein the feasible region represents a portion of the defined design space with data points corresponding to successful fabrications;
determining, using a regression model and the feasible region, predicted values for each data point in the feasible region, wherein the predicted values represent a mean value of the quality metric and a variance value for each data point in the feasible region;
calculating a score for each data point in the feasible region, wherein the score is a weighted average of the mean value and the variance value from the predicted values of the corresponding data point;
selecting one or more recommended data points, each recommended data point representing a recommended set of process parameters, based on a ranking of the data points in the feasible region corresponding to the score of each data point;
receiving experimental results corresponding to the one or more recommended data points, each experimental result including a quality metric;
determining a set of one or more optimal data points from the recommended data points based on the corresponding quality metric satisfying a predetermined range or threshold for the quality metric; and
outputting the set of one or more optimal data points and/or corresponding one or more optimal process parameters.

Another aspect of the technology is a computer implemented method similar to the above method, but wherein the following steps are performed prior to performing the above method:
receiving initial data, wherein the initial data includes a set of one or more initial data points and corresponding results for the fabrication process, each initial data point representing a set of one or more process parameters for the fabrication process and wherein the results include a success indicator and a quality metric representing a measurement of the fabrication process for each set of process parameters, wherein the success indicator indicates success or failure of the fabrication in satisfying the predetermined range or threshold for the quality metric;
determining an initial feasible region from the initial data and using the classification model, wherein the feasible region represents the portion of the defined design space with data points corresponding to successful fabrications;
determining, using the regression model and the feasible region, initial predicted values for each data point in the initial feasible region, wherein the initial predicted values represent an initial mean value of the quality metric and an initial variance value for each data point in the initial feasible region;
calculating an initial score for each data point in the initial feasible region, wherein the initial score is a weighted average of the initial mean value and the initial variance value from the initial predicted values of the corresponding data point;
selecting one or more initial recommended data points based on a ranking of the data points in the initial feasible region corresponding to the initial score of each data point;
receiving initial experimental results corresponding to the one or more initial recommended data points, each initial experimental result including a quality metric; and
setting the initial recommended data points and corresponding initial experimental results as the process data.

The technology can be further summarized with the following list of features.
1. A computer-implemented method for optimizing a fabrication process, the method comprising:
   receiving process data, wherein the process data includes a set of data points, each data point representing a set of one or more process parameters for the fabrication process and corresponding results for the fabrication process, wherein the set of data points are sampled from a defined design space of process parameter values, and wherein the results include a success indicator representing a successful fabrication and a quality metric representing a measurement of the fabrication process for each set of process parameters;
   determining a feasible region from the process data and using a classification model, wherein the feasible region represents a portion of the defined design space with data points corresponding to successful fabrications;
   determining, using a regression model and the feasible region, predicted values for each data point in the feasible region, wherein the predicted values represent a mean value of the quality metric and a variance value for each data point in the feasible region;
   calculating a score for each data point in the feasible region, wherein the score is a weighted average of the mean value and the variance value from the predicted values of the corresponding data point;
   selecting one or more recommended data points, each recommended data point representing a recommended set of process parameters, based on a ranking of the data points in the feasible region corresponding to the score of each data point;
   receiving experimental results corresponding to the one or more recommended data points, each experimental result including a quality metric;
   determining a set of one or more optimal data points from the recommended data points based on the corresponding quality metric satisfying a predetermined range or threshold for the quality metric; and
   outputting the set of one or more optimal data points and/or corresponding one or more optimal process parameters.
2. The computer implemented method of feature 1, wherein prior to receiving the process data, the method further comprises:
   receiving initial data, wherein the initial data includes a set of one or more initial data points and corresponding results for the fabrication process, each initial data point representing a set of one or more process parameters for the fabrication process and wherein the results include a success indicator and a quality metric representing a measurement of the fabrication process for each set of process parameters, wherein the success indicator indicates success or failure of the fabrication in satisfying the predetermined range or threshold for the quality metric;
   determining an initial feasible region from the initial data and using the classification model, wherein the feasible region represents the portion of the defined design space with data points corresponding to successful fabrications;
   determining, using the regression model and the feasible region, initial predicted values for each data point in the initial feasible region, wherein the initial predicted values represent an initial mean value of the quality metric and an initial variance value for each data point in the initial feasible region;
   calculating an initial score for each data point in the initial feasible region, wherein the initial score is a weighted average of the initial mean value and the initial variance value from the initial predicted values of the corresponding data point;
   selecting one or more initial recommended data points based on a ranking of the data points in the initial feasible region corresponding to the initial score of each data point;
   receiving initial experimental results corresponding to the one or more initial recommended data points, each initial experimental result including a quality metric; and
   repeating the method if the quality metric of the initial experimental results fails to satisfy the pre-determined range or threshold for the quality metric.
   setting the initial recommended data points and corresponding initial experimental results as the process data.
3. The computer implemented method of feature 2, further comprising:
   determining, using the classification model, a probability value for each data point of the defined design space, the probability value representing a probability of success for the fabrication process;
   calculating, based on the probability value, an uncertainty value for each data point of the defined design space;
   selecting one or more data points from the defined design space, as one or more uncertain data points, based on a ranking of the data points of the defined design space corresponding to the uncertainty value of each data point; and
   adding the one or more uncertain data points to the initial recommended data points; and
   wherein the one or more uncertain data points are included in the initial recommended data points for the performance of the fabrication process.
4. The computer implemented method of feature 2, further comprising:
   selecting one or more variance data points based on a ranking of the data points in the initial feasible region corresponding to the variance value from the initial prediction values of each data point;
   adding the one or more variance data points to the initial recommended data points; and
   wherein the one or more variance data points are included in the initial recommended data points for the performance of the fabrication process.
5. The computer implemented method of feature 2, further comprising:
   processing the initial data with the classification model to further train the classification model; and/or
   processing the initial data with the regression model to further train the regression model.
6. The computer implemented method of feature 1, wherein determining the feasible region further comprises:
   determining, using the classification model, a probability value for each data point of the defined design space, the probability value representing a probability of success for the fabrication process; and
   determining the feasible region based on data points of the defined design space with corresponding probability value that exceeds a feasible threshold value.
7. The computer implemented method of feature 1, wherein defined design space comprises at least one range of feasible values corresponding to at least one process parameter for the fabrication process and with at least one defined step value for the at least one range of feasible values that is used to determine data points within the defined design space.
8. The computer implemented method of feature 1, wherein after selecting one or more recommended data points, the computer implemented method further comprises:
   sending instructions to a fabrication device, wherein the instructions include the one or more recommended data points and a command to execute one or more fabrication processes using the one or more recommended data points; and
   wherein the experimental results corresponding to the one or more recommended data points are received from the fabrication device.
9. The computer implemented method of feature 1, wherein the fabrication process comprises chemical synthesis, an additive manufacturing process, a machining process, fabrication of a device, fabrication of a nanomaterial, fabrication of a metamaterial, fabrication of a microelectronic or nanoelectronic chip, fabrication of a sensor, fabrication of a MEMS or NEMS device, fabrication of a magnetic material, synthesis of a drug, formulation of a drug, a crystallization process such as a protein crystallization process, engineering of a cell, protein, or gene, or sequencing of a nucleic acid such as sequencing of a genome.
10. The computer implemented method of feature 1, wherein the fabrication process comprises one or more of a chemical vapor deposition process, a metal organic chemical vapor deposition process, a physical vapor deposition process, or atomic layer deposition process.
11. The computer implemented method of feature 10, wherein the fabrication process comprises use of chemical vapor deposition to synthesize a 2D material.
12. The computer implemented method of feature 1, wherein the process parameters include one or more of temperature, pressure, humidity, pH, concentration of one or more reactants or intermediates, presence or absence or type of a catalyst, presence or concentration of solvent, presence or type of solid support, flow rate or composition of a gas or solution, choice or amount of a reactant or material, physical separation of reactants, or form of a component or device used in the fabrication process.
13. The computer implemented method of feature 1, wherein the classification model is trained with a training dataset comprising at least one multivariate input-output pair labeled with a feasibility value corresponding to the probability of a successful fabrication process.
14. The computer implemented method of feature 1, wherein the classification model is a semi-supervised classification model.
15. The computer implemented method of feature 1, wherein the regression model is a Gaussian Process regression model.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 illustrates a closed-loop framework for a data-driven sequential optimization method for design of experiments, in accordance with some embodiments.

FIG. 2 illustrates a flowchart for operations involved in the optimization process of the data-driven sequential optimization method, in accordance with some embodiments.

FIG. 3A illustrates an example of a three-parameter design space, such as parameters for 2D material synthesis, in accordance with some embodiments.

FIG. 3B illustrates a visualization of variance of predictions for outputs of a regression model given input values, where the input values are along the x-axis and the output values are along the y-axis, in accordance with some embodiments.

FIG. 3C illustrates an updating process for a constraint model (e.g., classification model) of selecting data points near a classification boundary to refine the classification boundary and constraint model, in accordance with some embodiments.

FIG. 4 illustrates a schematic overview of the ML-guided iterative synthesis workflow, in accordance with some embodiments. FIG. 4 further illustrates a set of 26 un-optimized synthesis runs providing initial training data. Only 8 of these runs resulted in any observable growth. FIG. 4 further illustrates a schematic representation of a CVD furnace, with various possible design of experiment (DoE) parameters. FIG. 4 further illustrates Photoluminescence (PL) spectrometry to characterize the grown samples. FIG. 4 further illustrates the DoE conditions and the label of feasibility for design fed into the constraint (classification) model to identify a feasible design space and the DoE conditions and feasible linewidth data are fed into a regression model to identify the process-to-property relationship. FIG. 4 further illustrates 5D prediction maps (only 3D is visualizable) provided to a query generator, which uses a Bayesian optimization method to generate DoE recommendations for the next growth iteration. FIG. 4 further illustrates samples as labeled, stored, and performing additional characterizations.

FIG. 5A shows a fluorescence image of 2D MoS₂ grown under an un-optimized DoE condition. The image superimposes a grey-scale filter-less backscattered image under a 488 nm illumination and a PL-selective filtered image in red. Only some regions of the triangular-shaped crystals have PL responses, as the synthesis resulted in a mixture of monolayer regions (that have PL responses) and bi- and multi-layered regions (that do not have PL responses).

FIG. 5B shows an AFM topographical image with step heights ˜2.5 nm, confirming the 1-3 layer-thickness nature of some of the grown crystals.

FIG. 5C shows a typical Raman spectrum showing the A_{1g} and E¹_{2g} peaks. The 521-cm⁻¹ silicon peak from the SiO₂/Si substrate was used to normalize all Raman and photoluminescence (PL) data.

FIG. 5D shows the PL spectrum with the narrowest A-exciton linewidth (σ_{A}) obtained from the most optimized DoE parameter.

FIG. 5E shows variation of A-exciton linewidth (σ_{A}) in monolayer MoS₂ samples synthesized iteratively using ML-guided DoE parameters.

FIG. 5F shows variation of growth abundance factor with iteration. Here, abundance is defined as the percentage of attempts from multiple regions of the same sample where a PL spectrum was successfully obtained. A 100% abundance implies a PL spectrum was obtained successfully for all attempts.

FIG. 5G shows variation of abundance factor with σ_{A}. A clear correlation was found between high abundance factors and narrow values of σ_{A}, which led to the concurrent increase in abundance of the grown crystals along with quality.

FIG. 6 illustrates an iterative mapping of the 5D DoE hyperspace of MoS₂ synthesis for CVD. FIG. 6 further illustrates that an iteration starts with the prediction of a set of DoE parameters that guide the experimental synthesis, followed by PL characterizations. All previous and new data are fed into the constraint and regression models which generate the feasible design space. A 2D growth probability map over the full range of flow rate (F) and ramp rate (R) is shown for the most favorable DoE predicted values of P_{MS}, P_{S}, and t for the 7^{th} experimental iteration. Multiple regions with high growth probability are seen with at least 3 local maxima. FIG. 6 further illustrates a 2D map of predicted linewidth values for the same range of parameters, characterized by only one minimum and a small region where the linewidth would be narrower than 40 meV. FIG. 6 further illustrates that variance measures the prediction uncertainty of the regression model. The prediction uncertainty of DoE parameters located in the unexplored region in 5D maps is larger than those from DoE parameters located near labeled data. FIG. 6 further illustrates five DoE parameters are recommended by the query generator. The third DoE condition is for linewidth optimization, and the other four DoE conditions are recommended for the model update. The classification and regression model may be updated iteratively with all previous data (e.g., iterations) and the 5 new data from the next iteration. FIG. 6 further illustrates a new prediction of 2D growth probability, 2D linewidth maps generated from data collected from iterations 0-7, and a variance of linewidth prediction from the regression model with all previous data.

FIG. 7A illustrates a variation of experimentally measured σ_{A} for DoE parameter towards and away from the optimized DoE parameters.

FIG. 7B is a 3D illustration of the evolution of the 5D DoE parameter settings with iteration, summarizing how the parameters are changed at each iteration to eventually obtain samples with the lowest linewidth values. The parameter Pₛ in iterations 8, 9, and 10 shift to 1 cm that are different from iterations 1 to 7 (0 cm).

FIG. 7C shows a variation of classification accuracy with iteration. The classification accuracy grows steadily with iteration and reaches 100% by iteration 10.

FIG. 7D shows a variation of regression Mean Absolute Error (MAE) with iteration, calculated in the vicinity of the narrowest linewidth conditions. The MAE drops to about 4meV within the first few iterations and remains nearly constant after that, reflecting ˜90% accuracy of prediction beyond iteration 1.

FIGS. 8A-8C show selected fluorescence images of 2D MoS₂ grown in various DoE iterations. Each image comprises a grey-scale filter-less backscattered image taken under a 488 nm illumination, a black-red image selectively filtered between 580 nm and 758 nm for PL. FIG. 8A shows a selection from the optimizer of iteration 2. FIG. 8B shows a selection from the optimizer of iteration 4. FIG. 8C shows a selection from the optimizer of iteration 7.

FIG. 9 illustrates a high-level overview of the closed-loop framework for a data-driven sequential optimization method for design of experiments, in accordance with some embodiments.

FIG. 10A illustrates a ground truth of an objective function with infeasible regions, in accordance with some embodiments.

FIG. 10B illustrates an initial dataset with constraint labels indicating feasible and infeasible samples (labels of feasibility), in accordance with some embodiments.

FIG. 10C illustrates a graphical representation of an initial constraint model prediction with predicted feasible and predicted infeasible samples, in accordance with some embodiments.

FIG. 10D illustrates a graphical representation of prediction uncertainty for the constraint model, in accordance with some embodiments.

FIG. 11 illustrates a closed-loop framework for a data-driven sequential optimization method for design of experiments, in accordance with some embodiments.

FIG. 12 illustrates a graphical representation for convergence speed comparison for different frameworks over iterations with different sizes of initial data. Each curve represents the average results of 20 runs, and the shaded area shows a 95% confidence interval obtained from 20 repeated experiments with different sets of the initial datasets.

FIG. 13 illustrates a graphical representation for accuracy comparison of constraint learning with 10% initial labeled data for different frameworks over iterations. Each curve represents the average results of 20 runs.

FIG. 14 illustrates a schematic representation of a CVD furnace for MoS₂ synthesis experiments and material characterization of effectiveness using the data-driven sequential optimization method.

FIG. 15 illustrates a graphical representation for convergence speed comparison of linewidth (σ_{A}) optimization via different frameworks over multiple iterations.

FIG. 16 illustrates a graphical representation for accuracy comparison of constraint estimation via different methods over multiple iterations. Each curve represents the average F1 score of 20 runs.

FIG. 17 illustrates a graphical representation for convergence iteration of BO-ACL associated with different weight parameters for two initial data sizes in the case study.

### DETAILED DESCRIPTION

The present technology provides a computer implemented method for designing a fabrication process. The fabrication process is characterized by one or more process parameters that can affect the outcome of the fabrication process. The outcome of the fabrication process is characterized by one or more quality metrics or criteria by which the relative success of the fabrication process can be assessed. A range of desired values of one or more such quality metrics can be provided by a user at the outset of the optimization method. The final output of the method can be a set of process parameter values that produce an outcome within the desired range of the quality metrics specified at the outset.

The method uses a classification model in conjunction with a regression model, both using artificial intelligence and trained using experimental and/or predicted results, to iteratively recommend process parameter values or “data points” for performing real world fabrication experiments. The experimental results can be used to expand the set of data points accessed by the models and used to iteratively predict revised recommended process parameters, until process parameters have been identified that produce experimental results within the desired range of the one or more quality metrics.

The process for optimization by the present technology can be any process requiring optimization involving real world trials or experimentation to achieve an optimum result. The technology is particularly suited to optimize processes that include a number of process steps, such as one or more, two or more, three or more, four or more, five or more, six or more, seven or more, eight or more, nine or more, ten or more, 3-5, 3-7, 3-10, 5-7, 5-10, 10-15, or 10-20 steps toward completion of a product or outcome. For example, the process can be a process used to fabricate, produce, or synthesize a chemical substance, a material, a drug, a recombinant or engineered enzyme or protein, a recombinant or engineered cell or living organism, a device, a machine, or a method to be carried out by a human or a machine. The process can be a chemical vapor deposition process, a metal organic chemical vapor deposition process, a physical vapor deposition process, or atomic layer deposition process. The process can be a process used in semiconductor chip (e.g., microelectronic chip, nanoelectronic chip) manufacture or sensor manufacture. The process can be a photolithography or electron beam lithography process. The process can be a fabrication process for a microelectromechanical systems (MEMS) device or for a nanoelectromechanical systems (NEMS) device. The process can be a 3D printing process. The process can be a process for manufacturing a medical device. The process can be a metabolic or biosynthetic process carried out by a living organism or cell. The order of steps of a process can be optimized. The process parameters for optimization also can be, for example, conditions used during a process, such as temperature, pressure, humidity, pH, concentration of one or more reactants or intermediates, presence or absence or type of a catalyst, presence or concentration of solvent, presence or type of a solid support, flow rate or composition of a gas or solution, choice or amount of a reactant or material, physical separation of reactants, or form of a component or device used in the fabrication process.

The integration of machine learning (ML) techniques holds significant promise in999 expediting the process of optimizing the parameters of synthesizing high-quality materials. By leveraging ML algorithms, researchers can harness patterns and correlations within data to navigate the intricate DoE space more efficiently. [8] One of the key advantages of employing ML is its ability to extrapolate insights from a relatively small initial experimental dataset, which mitigates the need for exhaustive experiments, thus significantly reducing costs and accelerating the development process. Active learning is a subfield of ML—an iterative learning method which can start with a small initial dataset. [9] Under the active learning framework, Bayesian Optimization (BO) is a kind of global optimization method that leverages probabilistic ML, such as Bayesian regression [10] and Gaussian Process [11], in order to find the global optimum with the least experimental cost. Previous works have successfully demonstrated ML as a tool for optimizing the synthesis of flash graphene [12], nanotubes [13] and perovskite nanocrystals [14]. Furthermore, ML can also reveal hidden relationships among DoE parameters that might have overwise been overlooked due to complex parameter interdependencies, such as gas flow rate and pressure in the CVD reactor. [15,16].

Despite these promising merits of ML in materials synthesis optimization, several challenges persist. At the earliest stages of material development, conventional ML-assisted synthesis efforts are forced to rely on a limited amount of historical experiment data. [17-19] This scarcity of initial experimental data limits the training dataset for conventional ML models, potentially affecting their performance (i.e., accuracy and generalizability). Hence, these ML models do not adequately reduce the experimental burden making them impractical for accelerating the maturity of early-stage CVD-based material synthesis, for example. As CVD often involves chemical reactions under dynamic non-equilibrium conditions, physics-guided ML models are not trivial to build. [20] Further, as the number of design parameters increases, the complexity of the DoE space escalates sharply, requiring advanced techniques that integrate ML with optimization methods to efficiently explore and determine the ideal synthesis parameters within the multi-dimensional design space. [21] Moreover, in the entire design space, feasible and infeasible regions denote the success or failure of the synthesis sample, respectively. Clearly identifying the boundaries between these regions is crucial for minimizing the effort required in parameters exploration. [22] Unfortunately, verifying whether a design meets the feasibility constraint, such as determining if the 2D material is in the form of a monolayer, often requires further resource-intensive experiments. [16]

The methods and techniques described herein introduce an adaptive experimental design strategy that synergizes a constraint learning model—implemented through a classification model—with Bayesian optimization, named Constrained BO. This integration enables efficient exploration across a multi-dimensional DoE landscape and identify optimal synthesis parameters for high-quality 2D materials. First, a feasible 5-dimensional DoE parameter space is defined that comprises monolayer MoS₂ growth with a relative photoluminescence (PL) intensity above 0.05 when normalized by the silicon 521 cm⁻¹ Raman peak, and the A-exciton linewidth value below 70 meV. Subsequently, the narrowness of the A-exciton linewidth, σA, is selected as a measure of high quality of the as-grown MoS₂ crystals [23]. Employing a dynamically updated constraint learning model, we estimate the boundary within the DoE hyperspace, distinguishing between regions where 2D monolayer crystal growth is probable those where it is likely to fail. With the “successful” regions identified, our optimization framework narrows its focus exclusively to these “successful” regions to search for the optimal experimental conditions. Finally, an ML surrogate model is employed, using a statistical approximation of the target quality, coupled with a query generator based on multiple sampling criteria. This approach is used to recommend synthesis parameters for improved target quality (narrower σA) and to improve the estimation of unknown constraint function that distinguish between successful and failed conditions for monolayer crystal growth within the DoE space. Through successful iterative implementation and validation of MoS₂ synthesis and characterization steps, this method is able to achieve high accuracy and reliability even with limited experimental data (only 15% of the experimental data compared required for with needs of a full factorial design) and minimal additional trials suggested by the sampling recommendation algorithm. This novel approach stands out in its effectiveness in fast learning and attaining the highest possible material quality, while minimizing the need for extensive additional experiments.

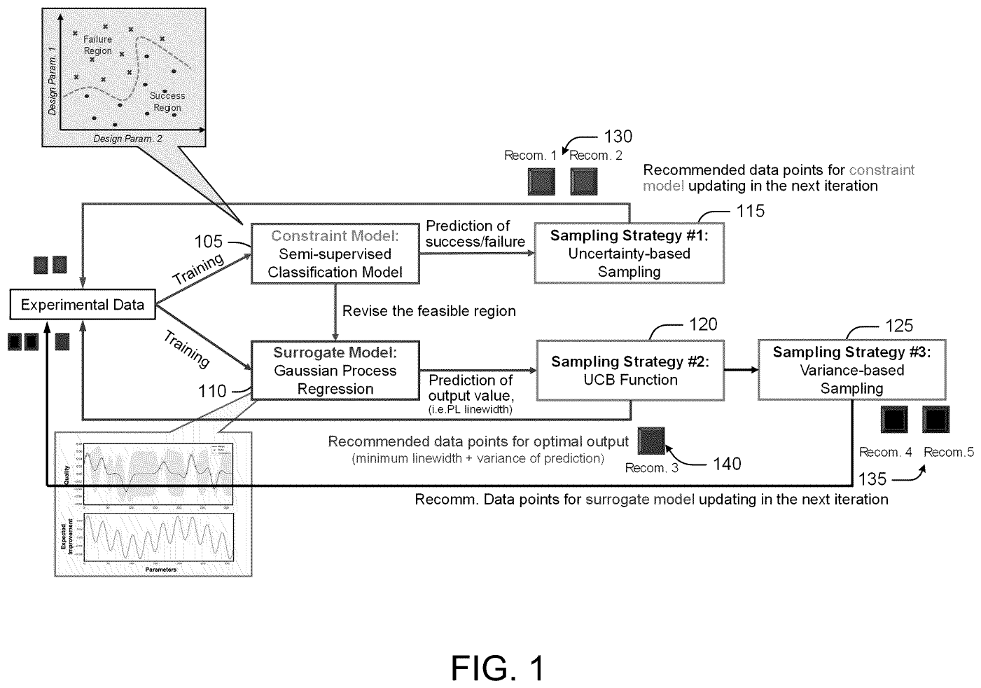

Described herein is methodology for the Constrained BO method as a data-driven sequential optimization method for design of experiments in detail. As shown in FIG. 1, the overall modeling framework utilizes a closed-loop framework with two major components: (i) a constraint model 105 to identify the decision boundary between “success” and “failure” samples, and (ii) a surrogate model 110 to predict the synthesis outcome (i.e., A-exciton linewidth from photoluminescence of a two-dimensional material). These two components interact with each other, and their predictive outcomes guide the selection of informative samples for the subsequent batch of experiments. Specifically, the constraint model 105, functioning as a binary classifier, is employed to predict the boundary that distinguishes between successful DoE parameters (e.g., produced MoS₂ flakes having significant PL peak intensity and value of the A-exciton linewidth less than 70meV) and unsuccessful parameters. However, the specific boundary is unknown and needs to be learned through an active learning procedure. Contrary to traditional methods such as safe-aware Bayesian optimization [35,36], which assumes that the constraints are uninformative, the constraint model 105 provides meaningful regional information for the production of monolayer flakes. A Graph-based Semi-Supervised Classification Model (GSSCM) [37] may be used to classify data points in the design space as “success” or “failure” samples, updating the boundary iteratively as the data from new trials are appended. In the trial data, each data point can be assigned a success indicator that, for example, labels data points as “success” if a quality metric falls within a pre-determined range or falls above or below a pre-determined threshold for the quality metric. The package Scikit-Learn is used to build the GSSCM, and the geometric information of all DoE parameters is measured using an RBF kernel function. Given the prediction of successful experimental regions from the constraint model 105, the GPR-based surrogate model 110 is then built to predict the target function, capturing the relationship between the process parameters and linewidth. The surrogate model 110 (e.g., the regression model) is trained via the package GPy with the Matern5 Kernel function. Combining the sampling recommendations derived from both classification and regression results, this establishes the parameters for the subsequent experiment.

As shown in FIG. 1, the predictions of growth probability from the constraint model 105 and the A-exciton linewidth predictions from the surrogate model 110 (e.g., the regression model) are fed into the experimental design. This design leverages multiple sampling strategies to identify the most informative, untested samples. The multiple sampling method uses three sampling strategies. First sampling strategy 115 includes selecting the most informative unlabeled DoE parameters for refining the classification boundary. The second sampling strategy 120 includes seeking the optimal experimental parameters that yield the narrowest linewidth. The third sampling strategy 125 includes choosing unlabeled DoE parameters to retrain the surrogate model 110. Unlabeled DoE parameters are those not associated with an actual experimental result.

In each subsequent round, two sets of DoE parameters 130 are recommended with the largest classification uncertainty to explore the classification boundary further, and two sets of DoE parameters 135 that exhibit the highest predicted variance to examine the surrogate model 110 (e.g., the regression model) more closely. These four samples are recommended via an uncertainty sampling strategy [38] to improve the performance of the classification and regression models with the least human effort. Additionally, a set of DoE parameters 140 is suggested using the acquisition function integral to the traditional Bayesian Optimization paradigm. The Upper Confidence Bound (UCB) acquisition function is used, setting β=100 based on the numerical scale of the predicted mean and variance terms.

The methods and techniques described herein are for a machine-learning guided optimization of a fabrication process, such as a process for synthesis of a 2D material, but may be utilized in other fabrication processes such as 3D printing. In some embodiments, the optimization method may receive an initial set of experimental data as input. The experimental data represent a set of process variables or parameters for performing a particular fabrication process. For example, for a 2D material synthesis, the experimental data might include gas flow rate, furnace temperature, heating time, and/or relative position of the reactant materials. Labeled experimental data also include corresponding results for the particular 2D material synthesis using a set of process variables or parameters. These corresponding results may further include a success or failure indicator, such as a binary value. The corresponding results may also include one or more measurements or characteristics of the resulting synthesized material, i.e., quality metrics. Quality metrics provide a measure, preferably quantitative, of a significant or desired feature or characteristic of the product resulting from the fabrication process, or of the process itself. The one or more quality metrics are preferably selected as the basis for optimization of the fabrication process. Examples of quality metrics include linewidth of the A-exciton photoluminescence spectrum in the case of synthesis of a 2D material, other measures of material uniformity, quality, or yield, cost of production, selection or consumption of starting materials, energy consumption, and time of duration for the process or one or more key steps. The user may select any criterion associated with the fabrication process or its product as a quality metric.

Preparation for carrying out the optimization method may include training the two models, i.e., the constraint model and the surrogate model, and defining the design space. In some embodiments, the constraint model may be a classifier model, such as a model using a semi-supervised classifier. A training dataset for the constraint model may include data pairs, with the first part of the pair being a particular set of values for the process variables and the second part of the pair being the corresponding result of the material synthesis for those process variable values represented as a binary classification value for success or failure. For example, in the 2D material CVD synthetic process, if the A-exciton linewidth value σ_{A} of the photoluminescence is below 70 meV, the synthesis is classified as “success” (e.g., binary value of 1); otherwise, it is classified as “failure” (e.g., binary value of 0). The trained constraint model may provide a prediction of the probability of “success” or material growth probability (e.g., a value, a percentage) for a given set of parameter values.

In some embodiments, the surrogate model may be a regression model, such as a Gaussian Process Regression model. A training dataset for the surrogate model may comprise a similar set of data pairs as the constraint model training dataset with the same set of values for the process variables as the first part of the pair, but instead the second part of the pair being an outcome measurement or feature of a target fabricated material property, such as photoluminescence linewidth. The trained surrogate model may predict a fabrication quality metric in the form of mean value and variance. The mean value represents the most likely value of the quality metric and the variance represents the uncertainty of the predicted value. For example, in a 2D material CVD synthetic process, the surrogate model may predict the exciton A PL linewidth, σA, and its variance.

Finally, a design space is defined for the particular fabrication process and the respective process variables that are being optimized. The design space provides a reasonably feasible range of values corresponding to each of the process variables to be optimized for the fabrication process. Thus, the design space can be a multidimensional space with the number of dimensions corresponding to the number of process variables being optimized. The range for each process variable may be preconfigured by a user based on user experience or theoretical physical limits or other theoretical considerations.

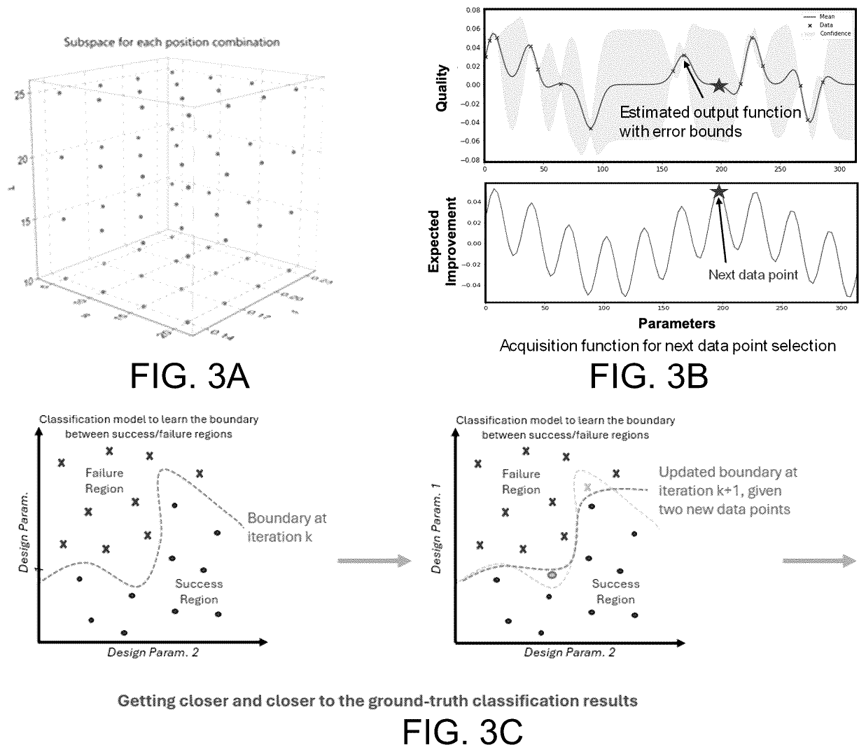

In addition to a range of values, a step size or grid size may be defined for the design space. The step or grid size is used to determine the potential sample process variable values may be selected from the design space values. The step or grid size may vary based on the range and the number of values desired to be in the sample set. For example, for a temperature range from 20 to 40° C., a step size of 5 may be defined, thus resulting in sample values such as 20, 25, 30, 35, and 40. In another example, the range may be from 0.0 to 1.0 with a step size defined as 0.1, thus resulting in sample values such as 0.0, 0.1, 0.2, etc. FIG. 3A is an illustration of an example three-parameter design space with a defined grid size for each parameter that subsequently identifies the sampling set of the design space (as illustrated by the dots).

Before performing the optimization process, the constraint model and surrogate model are trained using the respective constraint model training dataset and surrogate model training dataset, as described above. The size and variation of data in the training sets may impact the accuracy of the models. As the constraint model is trained, a feasible region of the design space may be determined. The feasible region represents a portion of the design space that has feasible parameter values based on the success and failure indications of the training data. For example, given a parameter with a range from 0 to 10, if all the failure results correspond to parameter values below 4 and all the success results correspond to parameter values above 4, then the feasible region may be defined as values above 4. The feasible region is utilized to guide the selection new parameters values (e.g., samples) for conducting experiments, as optimal new parameter values would come from a portion of the design space that is likely to have successful results. The feasible region is an evolving region that changes as the constraint model is trained with each iteration.

The optimization process may be implemented on a computer. The computer may include a hardware processor (e.g., a central processing unit (CPU), a graphics processing unit (GPU), a hardware processor core, or any combination thereof), a main memory and a static memory, some or all of which may communicate with each other via an interlink (e.g., bus). The computer may further include a display unit, an alphanumeric input device (e.g., a keyboard), and a user interface (UI) navigation device (e.g., a mouse). In an example, the display unit, input device, and UI navigation device may be a touch screen display. The computer may additionally include a storage device (e.g., drive unit). The storage device may include a machine readable medium on which is stored one or more sets of data structures or instructions (e.g., software) embodying or utilized by any one or more of the techniques or functions described herein. The instructions may also reside, completely or at least partially, within the main memory, within static memory, or within the hardware processor during execution thereof by the computer.

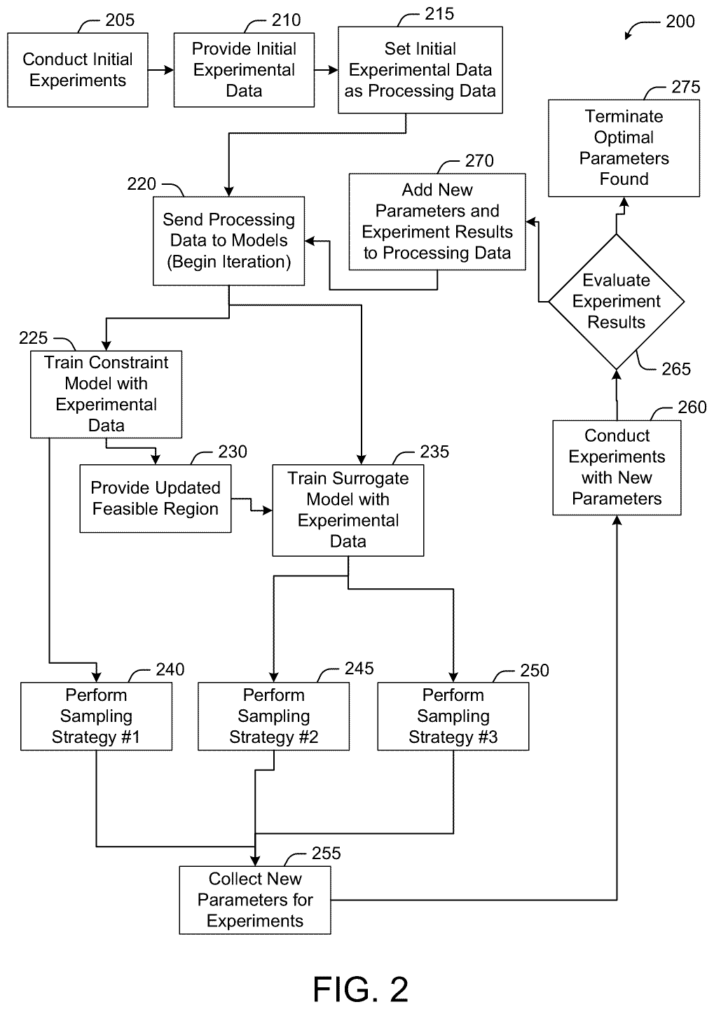

FIG. 2 is a flowchart illustrating the optimization process 200, in accordance with some embodiments. After the constraint model and surrogate model are initially trained and the design space is defined, including the feasible region, at step 205, a set of experiments (e.g., the fabrication process) may be performed using parameter values from the design space. The parameter values and the corresponding results of the experiments (e.g., success/failure, photoluminescence linewidth, etc.) may be provided, at step 210, to the computer as the initial experimental data. At step 215, the processing data is initialized by with the initial experimental data.

At step 220, an iteration of the optimization process begins and the processing data are provided to the constraint model and the surrogate model. At step 225, the constraint model is further trained with the processing data for the current iteration. The updated constraint model may then be used to update the feasible region of the design space and, at step 230, provide the feasible region to the surrogate model. At step 235, the surrogate model is further trained with the processing data for the current iteration. In some embodiments, the feasible region may be utilized to determine the parameters from the processing data that fall within the feasible region and limit the further training of the surrogate model to the data pairs of those parameters.

After performing the updated training of the models with the processing data, sampling is performed to collect a new set of parameter values that will be used for conducting one or more further experiments (i.e., fabrication runs). The optimization process may implement one or more of three sampling strategies. The number of samples (e.g., parameter values) collected from each sampling strategy may be defined by the user. For example, sampling strategy #1 may provide two samples, sampling strategy #2 may provide one sample, and sampling strategy #3 may provide two samples, for a total of five samples. These samples will be the parameter values provided in the processing data of the next iteration.

At step 240, sampling strategy #1 may be performed. The purpose of Sampling Strategy #1 is to select the most uncertain data points (i.e., parameter values), thus indicating less confident predictions, from the design space for experimentation. By performing experiments with these data points the aim is to obtain the true results and subsequently refine and update the constraint model. As shown in FIG. 3C, two parameters were selected for the k+1 iteration that fell near boundary, thus the actual experimental result for these parameters was uncertain. After performing the experiments and receiving the results for these parameters, the boundary shifts and becomes more refined.

Sampling strategy #1 leverages the probability results from the Constraint Model. The prediction uncertainty is quantified with the constraint model by calculating the absolute difference between success and failure percentages for a given data point in the design space.

For instance, if the constraint model predicts for a data point that there is 70% success, and thus equivalently a 30% failure, the uncertainty score may be calculated as |0.7−0.3|=0.4. For sampling strategy #1, the constraint model performs a prediction for each data point in the design space that has not already been included in the processing data and a corresponding uncertainty score is calculated for each of those data points. Data points in the design space are then ranked by the uncertainty scores in descending order. The top ranked data points are selected, depending on the defined sample number, as new data points (e.g., parameters) for the next-round experiment.

At step 245, sampling strategy #2 may be performed. The purpose of sampling strategy #2 is to select the data points that may be capable of exploring uncharted regions of the design space, while also exploiting regions that are likely to yield better results. Sampling strategy #2 aims to select data points from the design space that strike a balance between desirable target values and manageable prediction uncertainty. FIG. 3B illustrates the variance of predictions (shown as the shaded areas) of the surrogate model output (y-axis) given the input values (x-axis). The surrogate model is used to predict the variance and mean for each data point in the design space that has not already been included in the processing data. For each data point in the design space, a weighted average score of the predicted mean and predicted variance is computed. The weighted average scores are ordered and the top ranked data point(s) are selected, depending on the defined sample number, as new data points (i.e., parameter values) for the next-round experiment.

At step 250, sampling strategy #3 may be performed. The purpose of sampling strategy #3 is to perform experiments for highly uncertain data points of the surrogate model and receive the true values that are used to refine the surrogate model, getting closer to the ground truth. The surrogate model is used to predict the variance value for each data point in the design space that has not already been included in the processing data. From these data points and corresponding variance values, data points are selected for refining the surrogate model. The predicted variance values may be ranked in descending order and the top ranked data point(s) are selected, depending on the defined sample number, as new data points for the next-round experiment.

At step 255, the samples, or new parameters, from the sampling strategies are collected. The new parameters may then be provided for conducting experiments (e.g., the fabrication process) using those new parameters. In some embodiments, the new parameters may be output, such as displayed on a screen, transmitted by a communication (e.g., email), or stored as data (e.g., a document or file) in a storage device. At step 260, experiments may be conducted using the new parameters. In some cases, a user may access the new parameter values, such as viewing on a screen or opening a document, to perform the experiments. In other embodiments, the experiments may be an automated or computerized process that is performed by a robot or the device (e.g., a 3D printer, a fabricator). In some embodiments, the results from the experiments with the new parameter values may be recorded by the user and entered into the computer. In some embodiments, a device or robot performing the experiments may record the results from the experiments with the new parameter values and transmit the results to the computer.

At decision 265, the experimental results are evaluated to determine if one or more optimal parameters have been determined. Optimal parameter determination may be based on the type of experiment being performed and a qualification provided by a user for identifying one or more optimal parameters, such as a quality metric value or other value, such as yield, cost availability of resources, and the like, above or below a threshold value or within a desired range. In some embodiments, the user may set an optimum parameter value based on theoretical physical considerations or other considerations. At decision 265, the evaluation may determine to terminate the iterative process when an objective quality of the experiment reaches the limit. For example, in the CVD process, once PL linewidth resulting from a particular parameter reaches the theoretical minimum value (e.g., around 38 meV), the iterative process may terminate and the particular parameter may be validated. In some embodiments, a threshold value may be defined for an objective of the experiment, where it is desired to obtain an objective value (e.g., result value) better than the defined threshold value. For example, at decision 265, the evaluation may determine to terminate the iterative process based on two conditions: whether the achieved objective value exceeds the threshold value and that after N consecutive iterations after optimal parameters were identified, a better optimal parameter has not been found.

Based on the evaluation of the experiment results at decision 265, at step 275, the optimization process may terminate as one or more optimal parameters have been identified. The one or more optimal parameters may be validated to confirm the results of the experiments conducted at step 260. If, at decision 265, the evaluation of the experiment results determines that an optimal parameter has not been identified, then the optimization process continues. At step 270, the new parameters and the respective experiment results (e.g., the results from step 260) are added to the processing data. The optimization process then returns to step 220 and the next iteration begins, using the updated processing data.

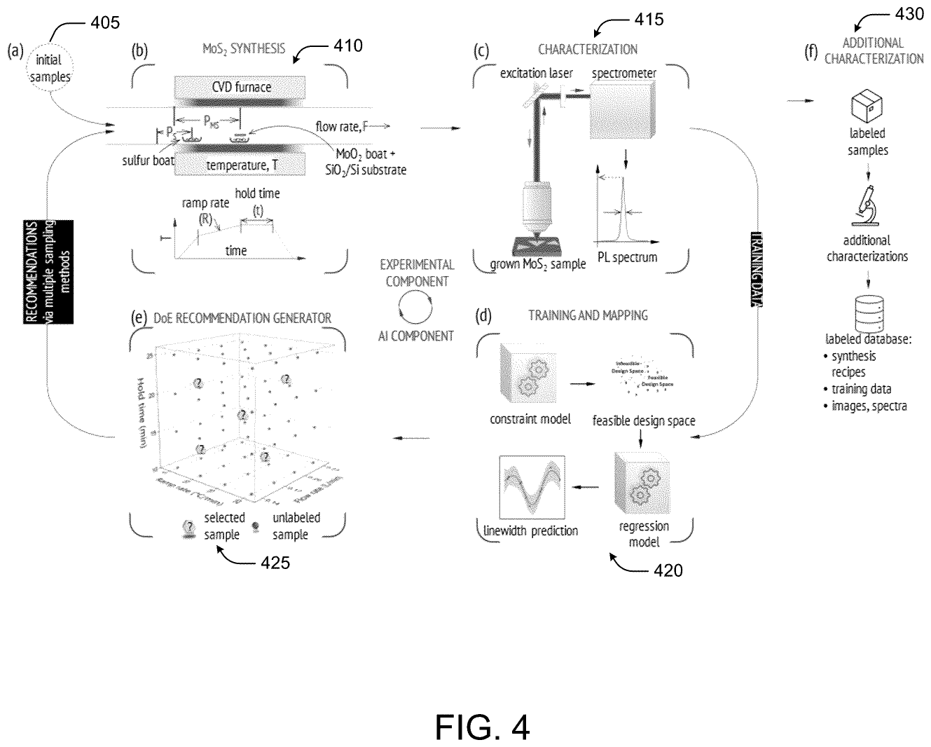

FIG. 4 outlines the iterative ML-guided experimental workflow developed in this work. Initially, a set of 26 experiments (iteration 0) was conducted by varying the CVD parameters to cover a range of previous unacceptably unsatisfactory or failed experiments 405. Out of these trials (or samples), only 8 resulted in monolayer growth. The five CVD DoE parameters 410 (positions of sources, flow rate, ramp rate, and hold time) varied, reflecting 384 trial possibilities. The narrowness of the A-exciton linewidth σA obtained from the photoluminescence (PL) spectrum of the grown samples was chosen as a fast and reliable post-synthesis measure of the optoelectronic quality of as-grown samples, which did not involve treatment or transfer. [23] σA is known to be narrower in higher quality 2D MoS₂, and gets significantly broadened due to defects and impurities in low-quality crystals. [24-27]

Starting from iteration 1, each iteration involved 5 experiments (as shown in large dots in 425): two of them (i.e., tests 1 and 2) to learn a dynamic classification boundary to estimate a “success” region of DoE parameters iteratively, one of them (i.e., test 3) to optimize the linewidth, and two other ones (i.e., tests 4 and 5) to obtain training data for updating the regression model. The selection of DoE parameters is autonomously managed by the machine learning algorithm beyond iteration 0, eliminating the need for human (i.e., CVD expertise) input. For each iteration, multiple PL measurements were conducted on the substrates to locate and characterize the 2D MoS₂ samples, both to determine success or failure, and to obtain the linewidth (σA) for the samples that were successfully grown 415—as a measure of their quality. The DoE parameters and the label of feasibility, σA values were entered into the constraint model (via a classification algorithm), the DoE parameters and σA values into and regression models 420. The constraint model separates the 5D DoE parameter space into “success” and “failure” regions, where the success space comprises MoS₂ growth with a relative PL intensity above 0.05 when normalized by the silicon 521 cm⁻¹ Raman peak, and a linewidth value below 70 meV. Separately, the regression model attempts to iteratively build a relation between 5D DoE parameters with linewidth using a probabilistic approach for predicted feasible design generated from our constraint model. Once trained on iteration 0 results, the probabilistic regression model generated five-dimensional (5D) visual maps of the mean and variance of predicted probability and linewidth for the full range of values for the 5 DoE parameters and meanwhile, the constraint model generated a contour map of probability for feasibility of design. As described below, with each iteration, these maps initially evolved and eventually converged to a set pattern, providing systematically improved conditions for higher-quality growth. A query generator 425 was designed via multiple sampling strategies to generate the suggested DoE parameters for the next iteration of experiments (e.g., the 5 sets of tests described above). The ML-guided experimental iterations were performed in two stages. Iterations in stage 1 were performed to find the optimized synthesis condition (DoE parameters) for the narrowest linewidth in the fastest possible time. This is the “brachistochrone” stage. Once linewidth obtained from recommended design reach to the theoretical minimum value (around 38 meV), it moves into stage 2. This second stage conducts cross-validation of the optimization by proposing DoE values that deviate from the optimized condition. This is done to test the robustness of our classification accuracy and prediction error, examining if better designs exist in both “near” and “away” from the most optimized DoE settings. These recommendations further affirm the robustness of the constraint model's accuracy by evaluating the prediction error of linewidth as determined by the regression model. In the end, an additional experiment, based on human decision, was performed to re-affirm the optimized condition. Additional characterizations 430 performed include Raman spectroscopy, fluorescence imaging, atomic force microscopy (AFM), and the data acquired from each of these steps, along with the DoE and PL data, and the samples, were labeled and stored.

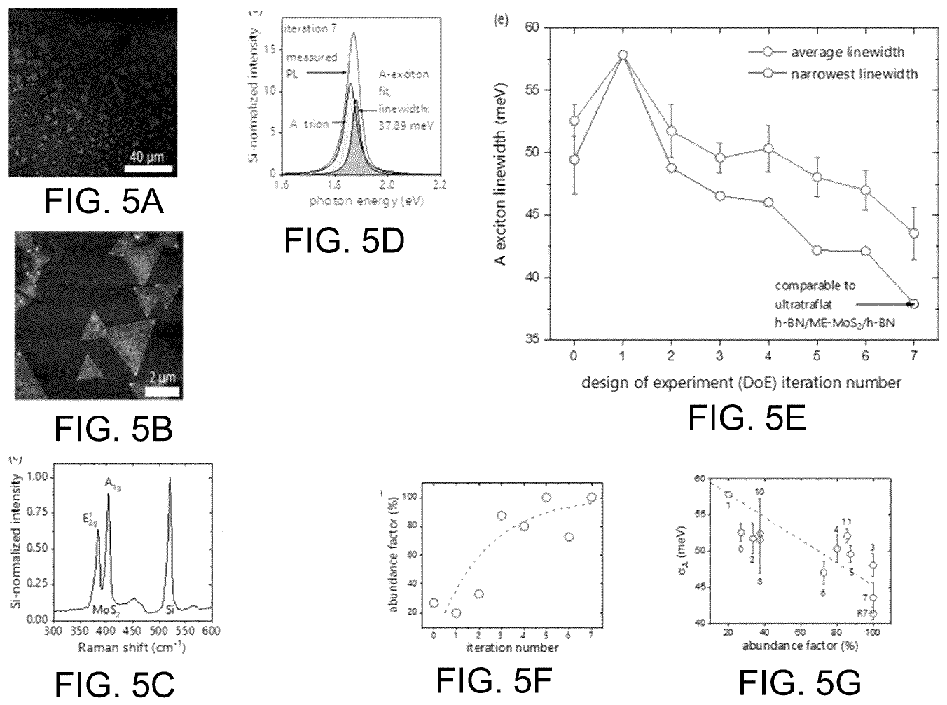

FIGS. 5A-5G highlights several important results of the Constrained BO-guided synthesis of 2D-MoS₂ layers. With each iteration, outcomes improved in stages from little or no growth of 2D layers, to intermediate growth combining monolayer and multilayer flakes, to abundant growth of largely monolayer 2D flakes with narrow σ_{A} values. Superimposed backscattered (grey pixels) and fluorescence (red pixels) images (FIG. 5A) taken from iteration 4 show strong fluorescence of 2D flakes in the top right region (suggesting that flakes that grew in these areas are primarily monolayered). Suppression of fluorescence from the other areas was attributed to multi-layered growth, which could be confirmed via AFM topographical images as shown in FIG. 5B. Since PL is greatly suppressed in all samples with 2 or greater layers, achieving strong PL peaks is also a good target parameter for ML to drive toward largely monolayer growth. Raman peaks corresponding to the signature A_{1g} and E¹_{2g} of MoS₂ with peak height as strong as those from the underlying Si substrate (FIG. 5C) confirm the well-formed crystals typically seen in iterations 5-7. FIG. 5D shows the PL peak deconvoluted to show the A-exciton and A-trion peaks. Taken from the iteration 7 sample, this represents the narrowest linewidth, s_{A}˜38 meV obtained in this work. The narrowness of exciton linewidth is a sensitive measure of the optoelectronic quality of monolayer MoS₂. Typical A-exciton linewidths found in CVD-grown and mechanically-exfoliated (ME) samples range between 45-90 meV and 40-75 meV, respectively. [28-34] A-exciton linewidths below 40meV can be achieved in ultraflat mechanically exfoliated samples obtained by sandwiching them between h-BN flakes, [31] and is rarely found in CVD-grown crystals. FIG. 5E shows how, starting with poor-quality samples with high (approaching 60 meV) s_{A} values, CVD-grown samples with narrow linewidths (average s_{A}˜46 meV, minimum s_{A}˜38 meV) can be achieved in a systematic, step-by-step manner. This may be the first time such a systematic sequence of experiments has been demonstrated to reach and reproducibly grow monolayer MoS₂ crystals with optoelectronic-grade quality comparable to that of ultraflat ME samples. The 57 trials conducted iterations 0 to 7, aimed at optimizing the CVD parameters, representing an approximate 85% reduction in the number of experiments required. This reduction is in comparison to the 384 full factorial design trials, which involve a specific design of the number of levels for each of the 5 parameters. It was planned with the following considerations: (i) insights from the experience with MoS₂ synthesis that identified parameter ranges with high chances for successful flake growth. This enabled to place lower- and upper-bounds, or limits, on each DoE parameter. (ii) The number of intervals (grid points) within a DoE parameter range for a standard CVD system, above which it was not possible to reproduce the experimental conditions using our instruments; and (iii) the total (real-time) scope of the experiments, which was equivalent of up to one year's worth of experimentation. This approach is also versatile, accommodating different DoE settings with variable levels. FIG. 5F shows how, with iteration, the abundance of successfully grown monolayer structures on the growth substrate grows, as a clear correlation exists between higher optoelectronic quality and abundance (FIG. 5G). Although the abundance factor was not programmed into the ML guidance algorithms, the correlation between conditions for high quality and high abundance is a highly desirable outcome.

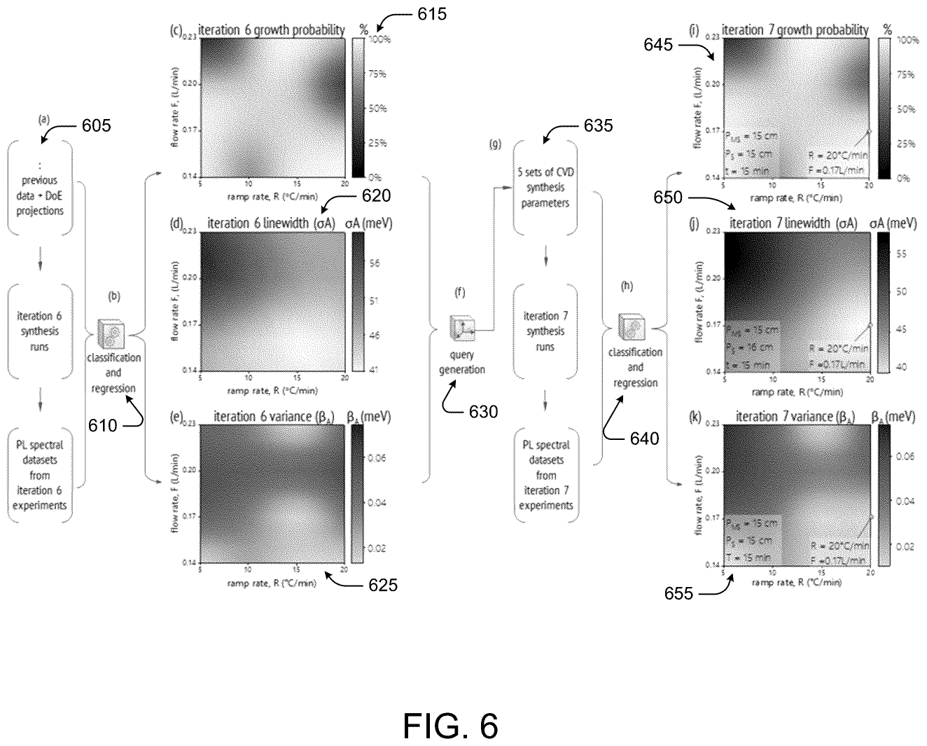

FIG. 6 showcases how these algorithms guide an experimentalist towards high-quality (narrow-s_{A}) monolayer MoS₂ synthesis by iteratively improved mapping of the performance of our CVD furnace. The 5 CVD parameters were varied; hence, all performance maps are five-dimensional (5D). All datasets obtained up to a certain point (e.g., prior to iteration 6 shown in 605) are fed into the constraint and regression models as represented in 610. The constraint model generates a feasible design space that is visualized via a 5D map of growth probability (0-100%) using labeled data (samples that were annotated with “success” or “failure” based on experiments), while the regression model provides 5D maps of the mean values and variances of the algorithm-predicted linewidth σ_{A}. 2D projections of these prediction maps as a function of the flow rate (F) and ramp rate (R) parameters are shown in 615, 620, and 625. The projections in 615 and 620 are immensely useful to an experimentalist who will be able to visualize the predicted DoE conditions for the highest growth probability and narrowest linewidth values for any two of the DoE parameters. As shown in FIG. 6, 625 shows a 2D projection of predicted variance corresponding to the predicted linewidth. This map is useful for an experimentalist to capture the DoE space that previous experiments did not cover. For example, as shown in 655, if one set of DoE parameters is realized by experiments, its predicted variance will reduce to 0, while unexplored or untested parameter sets remain high variance in the map. Taken together, these predictions from the feasibility constraints and regression models are used by the query generator 630 to generate the next set of 5 predicted DoE parameters. Three different recommendation strategies are implemented for each iteration to generate 5 sets of DoE parameters 635. The 5D map of growth probability (projected in 2D space in 615) is used to calculate the uncertainty of the classification boundary. The growth probability was treated as a classification problem where a classification boundary divides the DoE into two regions, e.g., parameters that result in “success” or “failure” of growth. In classification problems, data with high prediction uncertainty are always located near the classification boundary. Choosing unlabeled data (e.g., trials that are not yet realized by experiments) that are close to the boundary between “success” and “failure” categories allows the classification model to converge towards its most accurate state with the fewest number of experiments. In this approach, the query generator proposes two DoE parameters in each iteration to accelerate the convergence of the classification model. The 2D growth probability map over the full range of flow rate (F) and ramp rate (R) begins to converge after the 6th iteration when the other three parameters are set to the most favorable values (Pₘₛ=15 cm, Pₛ=0 cm, t=15 min). Similarly, to make the regression model converge as soon as possible, two DoE parameters are queried at each iteration. Different from the classification model, the uncertainty of predicted values in the regression model is measured by the prediction variance, which is calculated via a kernel function which measures the distance between labeled data and unlabeled data: data with high values of prediction variance are located far away from the labeled data. The query generator proposes two DoE parameters with the largest prediction variance to ensure that the experimental iterations cover the design space, focusing on DoE regions with the highest uncertainty values. In addition, the predicted linewidth and variance values are used to generate a DoE parameter (as represented for test 3 of iteration 7, 650) to seek the optimal setting with the narrowest linewidth. The classification and the regression model 640 are updated after the next synthesis trials (iteration 7 in this case). As shown in FIGS. 6, 650 and 655 show how the prediction linewidth and prediction variance changes in a 2D space after the 7^{th} iteration—where, noticeably—the non-zero prediction variance seen in the 6^{th} iteration at values around the suggested next optimal settings (R=20° C./min., F=0.17 L/min.) decease to 0 in the 7^{th} iteration.

The cycle then repeats 630-655 till the model performance is acceptable. The regression map in 645 evolves such that the global minimum for 6a moves closer to the experimentally observed DoE conditions for the narrowest observed σ_{A} values. These maps converged by iteration 7 (using only 61 out of possible 384 trials), suggesting the fastest possible convergence and arrival at the most optimized DoE parameter. Test 3 of iteration 7 gave us 2D-MoS₂ samples with the narrowest σ_{A} values, comparable to those found in the highest quality mechanically exfoliated samples. In real laboratory timescale, this optimization was achieved within 2 months, instead of the 12 months that a pure trial-and-error approach could have taken to cover the entire DoE hyperspace. Within this same timeframe, the CVD furnaces are also mapped out in detail. For the first time, this indicates that there are three growth probability maxima points (as seen in 615 and 645), whereas the σ_{A} map has only a single minimum (which is also the global minimum within this range, as seen in 620 and 650). Once converged, these maps provide a detailed visual guide to experimentalists identifying DoE-specific conditions under which they are most likely to succeed in growing 2D-MoS₂ and which of these conditions are most likely to result in the narrowest s_{A} values.

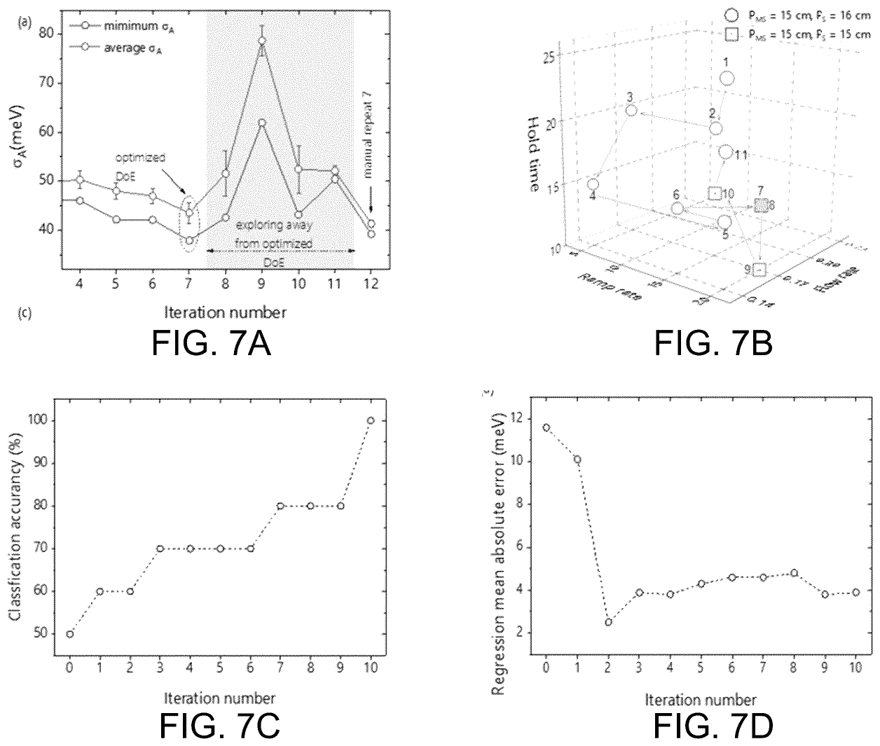

The remarkable effectiveness of the Constrained BO algorithms is showcased in FIGS. 7A-7D. The performance is first validated with the ML-guided framework on 3 more consecutive iterations and another five individual experiments beyond the experimentally achieved optimization point. This validation is used study to (1) confirm that the set of DoE parameters in iteration 7, test 3 is indeed the global optimal condition in the design space (i.e., the sweetest spot for highest-quality synthesis) and (2) to test the prediction accuracy of classification and regression models depicted in FIG. 4D. After iteration 7, the experiments continued via the designed query generator shown in FIG. 4E. The set of DoE parameters recommended via the acquisition function dynamically switches the searching focus from exploitation (iteration 4 to iteration 7) to exploration (iteration 8 to iteration 10) and then returns to exploitation (iteration 11). Three sets of DoE parameters (iteration 8, 9 and 10) shown in FIG. 7A explored the DoE conditions with high prediction variance to check whether other optimal conditions existed in the previously unexplored regions, and none of these regions returned good results, as seen by the high values of experimentally measured PL linewidth (FIG. 7A) for these. After 3 iterative explorations, the set of DoE parameters recommended in iteration 11 shifts back to exploitation to confirm that optimal DoE conditions are indeed located in the neighborhood of iteration 7 parameters, which—as seen in the figure—it did. As a final check, this is manually repeated an experimental run at the same DoE parameters of iteration 7 (shown as iteration 12)—which again resulted in the narrowest PL linewidth, as seen in FIG. 7A.

FIG. 7B is a 3D plot capturing how three of the synthesis parameters evolved with iterations, eventually resulting in the lowest linewidth values. The change in 5D “distance” between any two consecutive DoE parameter sets with each iteration reflects how the search focus (exploration vs. exploitation) evolves over iterations. The acquisition function controls the selection of unexperimented DoE parameters via balancing low linewidth prediction (exploitation) and high prediction uncertainty (exploration). This evolution aims to ensure that our sampling strategy sufficiently explores all regions where the optimal DoE could potentially exist, leveraging predictions from our regression mode. As an example, the DoE proposed in the 8^{th} iteration has a different sulfur boat position (P_{S}) parameter from iteration 7. This kind of shift would trigger a move out of the current local searching area to investigate if other optimal DoE values exist. The iterative experiments stopped at iteration 10 and our experimental validation started at iteration 11.

In iteration 11, another five sets of DoE parameters were selected with the least linewidth prediction value from the regression model trained by all collected data. Among these five sets of DoE parameters, the third set is the same as the recommendation to optimize the linewidth if the experiment continues via multiple sampling strategies. These five DoE conditions can not only be used to validate the performance of the regression model but also to demonstrate that the current set of optimal DoE parameters is a global optimum for the entire 5D DoE space. To test the performance of hybrid ML model, the performance of the classification model is separately evaluated to ensure the binary classification model may provide an accurate classifier to distinguish successful DoE parameters and failed parameters. Before the iterative procedure started, a leave-one-out cross-validation method is adopted to test the initial performance of the classification model. The initial prediction accuracy of the classification model was found to be 91.05%. FIG. 7C depicts how the performance of the classification model improves with iterations. After iteration 10, the classification model classified all 384 5D DoE parameters into a successful group with 200 sets and a failure group with 184 sets. Compared with the traditional Bayesian optimization framework considering a single objective to optimize, this framework can estimate a successful region of the whole design space to help material scientists eliminate trials that cannot generate our target material. The performance of this regression model is validated by its ability to accurately predict ‘successes’. To evaluate this regression model, the mean absolute error (MAE) was used as a metric due to the small scale of the linewidth. The prediction is only evaluated when this set of DoE parameters is predicted as a successful one correctly. FIG. 7D shows the remarkable result of how the MAE of the regression model converges to the lowest value of around 4meV (10% or better than the predicted values of σ_{A}) by just the 3rd iteration and remains more or less constant thereafter.

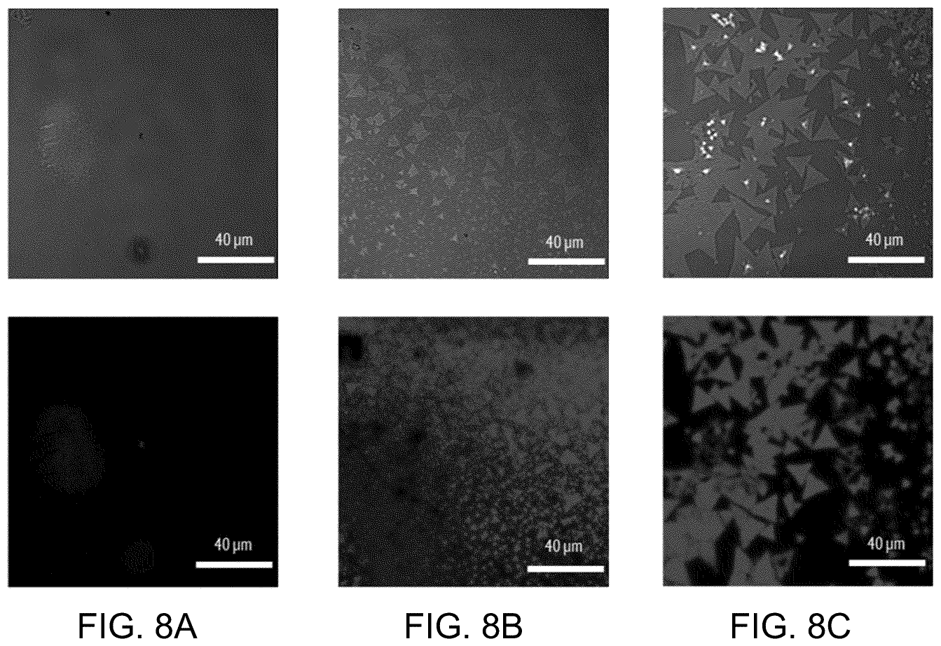

Finally, described herein is the iterative evolution of the overall spatial morphology (monolayer crystal size and surface coverage) and of the grown 2D MoS₂ crystals. The monolayer morphology showed steady improvement with iterations, consistent with the results in FIG. 5F, even though there was no active ML guidance towards growth with larger flake sizes or surface coverage. FIGS. 8A-8C present fluorescence microscope images of samples grown in iterations 2, 4, and 7. These images were obtained using a scanning confocal laser microscope, with samples illuminated by a 488 nm laser. The grayscale images in the top row are obtained using backscattered photons at the incident energy (488 nm), highlighting the progressively growing sizes of the crystals (images taken from each SiO₂/Si wafer where the crystal sizes were found to be the largest within the substrate). A clear progression of crystallite sizes is seen here. Further, when filtered for a window of wavelengths that are known to allow the well-known PL of monolayer MoS₂ flakes (580 nm-758 nm), the black-red scale images are produced (lower panel). This latter image type signifies the presence of monolayer-MoS₂. For these images, a fixed histogram range (0-6000 a.u.) was employed under equal illumination to compare their brightness. Under this parameterization, a higher PL intensity corresponds to increased brightness in the image, while a narrower PL linewidth is indicative of homogeneous brightness across the image. Consequently, the shape of the 2D crystal may be directly compared to its corresponding PL excitation area across iterations, not just within a single flake. The image for iteration 2 (FIG. 8A) displays a weak PL throughout the expected growth substrate. Iteration 4 (FIG. 8B) demonstrated noticeably stronger PL. The PL image from this iteration also reveals a dark-red background and numerous sub-micron MoS₂ dots, which reflect smaller and perhaps bi/multilayer crystals. The image from iteration 7 (FIG. 8C) exhibits a markedly stronger PL intensity in the corresponding MoS₂ growth area compared to both iteration 2 and iteration 4. Simultaneously, the image from this iteration presents a much higher prevalence of monolayer crystals of larger flake sizes compared to the previous iterations. In summary, the ML-guided approach improves the quality of the crystals and the overall morphology—which is a significant outcome of these investigations.

This study introduces an adaptive and sequential experimental design framework, utilizing machine learning to rapidly guide the synthesis of MoS₂ towards the highest possible quality with only 15% of the experimental data required by the traditional full factorial design method, and experimentally validates the effectiveness of this framework. This addresses a significant challenge encountered by the 2D materials synthesis community—namely, how to overcome the uncertainties involved in a multi-parameter 2D synthesis design space and quickly arrive at a specific outcome. There are several instances of novel and possible first-time demonstrations associated with this research. First, the ML models are used to learn and predict the growth conditions under which the linewidth of the A-exciton peak in a PL spectrum steadily narrows towards increasingly higher quality. In as-grown CVD samples, A-exciton linewidth values at or below 40 meV are quite unusual, and hence, this work showcases how the highest-optoelectronic-grade CVD MoS₂ could be achieved with the aid of machine learning. Second, an effective saving from the need to perform wasteful trials by about 85% is another highly valuable outcome—as it directly translates into dramatically reduced time, cost, and effort and increased chances of success for future material discovery efforts. Third, this algorithm and approach enables for providing experimentalists with easy-to-interpret 5D process-property contour maps of the CVD furnace, where regions of higher growth possibility and high quality can be easily visualized for all DoE parameters. This also validates the global minimum (within the tested range of DoE parameters) through a balance of “exploration” vs. “exploitation” steps. The algorithms enable to produce high accuracy, low error, and rapid convergence of maps within a few iterations. Taken together, these provide experimentalists with a high-confidence guided pathway towards specific synthesis goals.

The implications of these findings are significant, not only for the 2D materials community but also for broader nano and other materials synthesis communities where complex chemical reactions are very likely to impact materials optimizations. The algorithms are flexible enough to incorporate other “target” parameters beyond PL linewidth and can be easily modified to combine the effects of multiple target parameters to simultaneously optimize quality, yield, reproducibility, and other desired aspects of 2D material synthesis. Moreover, the algorithms developed can also be exploited by MBE, MOCVD, magnetron sputtering, and other complex techniques, including those that allow real-time monitoring of synthesis, such as RHEED. With the availability of larger databases, these trained algorithms are likely to be portable from one unit to another (similar) unit with very few changes. As a result, all future synthesis/manufacturing tools will essentially become integrated with ML-guided recipe optimization as a standard feature in the near future.

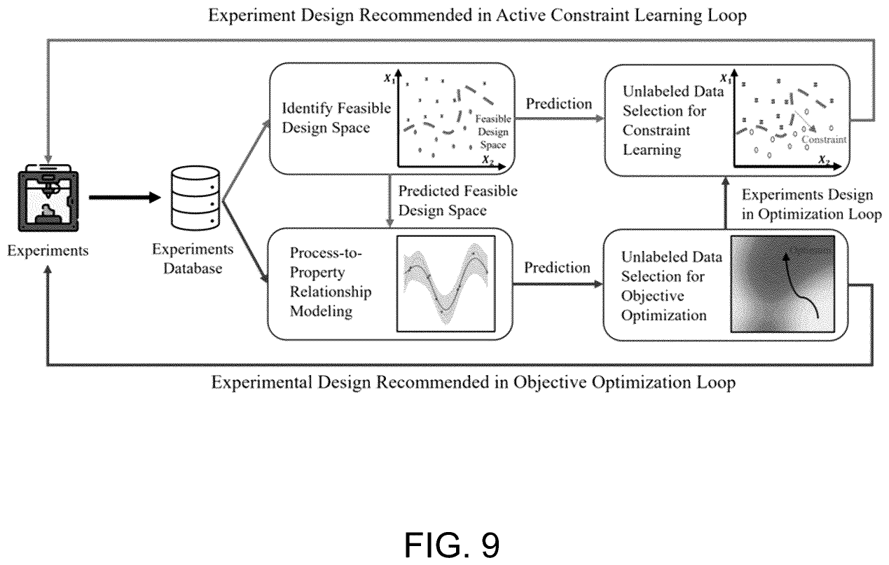

To address the key challenge mentioned in BayesOpt with incomplete knowledge of constraints, the methods and techniques described herein describe an innovative framework that synergizes AL and BayesOpt to optimize advanced manufacturing processes. This framework is designed to simultaneously explore the undefined constrained boundary and optimize the process, effectively harnessing the strength of both methodologies. The proposed framework, as illustrated in FIG. 9, consists of two main components: (1) objective optimization and (2) active constraint learning (ACL) loop. The optimization loop learns the process-to-quality relationship and proposes queries toward global optimization. The ACL loop learns the constraint boundary of process feasibility and chooses the most informative samples to be labeled in the next round. The ACL loop estimates the feasible region iteratively, which adapts over time to assist in optimizing the target process. Similarly, the query proposed from the optimization loop will also influence the selection in the ACL loop. The proposed framework offers several advantages, including exploring unknown feasibility constraints and optimizing the process under unknown constraints.

A constraint model may be introduced within the ACL loop to learn about feasibility constraints. Gaussian Process (GP), a widely used constraint model, may evaluate prediction uncertainty. A standard AL strategy queries the unlabeled sample near the classification boundary with the highest prediction uncertainty. However, the scarcity of labels and the complexity of the nonlinear relationship of process hinder the performance of the constraint model, which may lead to inaccurately classifying the true global optimal sample as part of infeasible regions. FIG. 2A illustrates the ground truth of the objective function where the global optimum ƒ*(x)=ƒ(0,0) is located in the center of the whole design space, and there are four infeasible regions. FIG. 2C illustrates the initial prediction result of the constraint model trained via labeled data shown in FIG. 2B. As shown in FIG. 2C, the global optimum is misclassified as an infeasible sample far from the predicted constraint boundary. Refining the feasible boundary via uncertainty-based sampling, as shown in FIG. 2D, would waste much effort correcting the decision boundary. The limited experimental dataset restricts the capability of the constraint model, making the sampling in the optimization loop stuck in a local-searching scenario where the true global optimum is ignored.

To improve the proficiency of this framework in simultaneously optimizing the target process and learning constraints, an active sampling strategy is devised that is founded on three key measurements: 1) representativeness, 2) uncertainty, and 3) diversity. This strategy employs a unified function in the active loop to select the most informative unlabeled samples. This approach may improve the optimization's convergence speed and facilitate the identification of the feasibility constraints with the least human effort.

As described herein, a novel parameter design method is introduced that leverages both active learning and Bayesian Optimization to effectively explore the undefined constraint boundary while optimizing the process concurrently. The designed framework avoids extensive human labeling via more effective constraint learning and faster convergence to the objective.

Additionally, a new multi-criteria sampling strategy is introduced that merges representativeness, uncertainty, and diversity measures. This strategy enhances the exploration of the implicit constraint boundary, enabling more efficient identification of the feasible region within the design space and thereby improving the optimization of the target process.

Finally, a novel heuristic sampling strategy is introduced to quantify the joint informativeness of samples queried in each iteration, further refining the sample selection process and improving optimization efficiency.

Active learning is widely adopted in machine learning applications when the labeling process is costly. Uncertainty and diversity are two of the most adopted criteria of AL for selecting unlabeled samples. Uncertainty-based methods, such as query-by-committee [43] and entropy-based sampling [59], choose unlabeled data with the most uncertain prediction to annotate labels for model retraining. Meanwhile, diversity represents the similarity between labeled and unlabeled data. Diversity-based methods choose the most dissimilar samples to query via different measurements, such as Euclidean distance and Cosine similarity. Previous research [67] designed a greedy sampling strategy to select the farthest sample from labeled data in the input and output space. Another study [64] proposed an AL sampling method that integrates uncertainty and diversity criteria via sparse modeling. However, samples are disproportionately labeled in different classes in active learning for real-world classification applications. Purely uncertainty-based and diversity-based methods will focus more on the majority class, which can degrade the performance. To tackle this problem, representativeness-based sampling strategies were proposed to quantify the impact of data density on the respective classifiers. Previous research [46, 51] combined the criteria of uncertainty and representativeness to optimize selection. Similarly, a recent study [56]proposed a cluster-based sampling strategy to unify the diversity and representativeness of unlabeled data to assign queries to different classes.

Studies have demonstrated that sampling methods considering multiple criteria simultaneously can improve AL performance. However, most previous research [55, 56, 60] on batch mode multi-criteria AL primarily focuses on clustering-based strategies. They usually first applied clustering methods to capture the underlying structure of unlabeled data and then defined representativeness and diversity based on the clustering results. However, identifying accurate clustering boundaries is challenging when unlabeled experimental samples are uniformly distributed across the predefined design space. In such cases, a recent study [52] measured representativeness and diversity using k-nearest neighbors and integrated uncertainty through a linear combination with static and predefined weighted parameters.

In machine learning literature, there are two main methodologies in BayesOpt under implicit constraints. This first type [47, 53] is interested in finding the global minimum x_{*} of an objective function ƒ(x) subject to non-negativity of a series of constraint functions c₁, c₂, . . . , cₖ. However, objective function ƒ(x) and constraint functions c, are unknown and can only be evaluated by experiments. This followed a design idea [58] that proposed a constrained acquisition function with a latent constraint function that multiples the probability of feasibility for each constraint. These methods refer to a safety-aware sampling strategy that integrates objective functions and constraints to make solutions feasible. However, the multiplier of feasibility probability cannot update the estimated feasible region to make constraints known.

An alternative approach to managing undefined constraints involves integrating an individual sampling criterion for constraint exploration. Recent work [54] designs a linear combined acquisition function integrating sampling strategy of feasible design updating and target process exploration. However, this work focuses on optimizing surrogate models globally without searching for optimal process parameters. In addition, a STA-GEOPT framework [61] was proposed to expand the estimated feasible region in the first stage and then implement typical BayesOpt within the predicted feasible space. A parallel optimization framework named pBO-2GP-3B [63] combines three acquisition functions to query a batch of unlabeled samples in each iteration. However, this work regards the AL and BayeOpt processes as two individual parts that propose queries independently. Within the AL process, they used a single criterion for the feasible region exploration, which is not very informative. The information extracted from the prediction in the first couple of iterations is unreliable due to the data scarcity problem. Consequently, overcoming the challenges posed by limited experimental data represents a critical research gap in applying Bayesian optimization within the manufacturing domain.

The methods and techniques described herein enhance the AL by implementing a dynamic weighted multi-criteria sampling strategy. As a key element of the framework, the active sampling method for the constraint model plays a significant role in improving decision boundary exploration. It also collaborates with the optimization process, thereby increasing the rate of optimization speed.

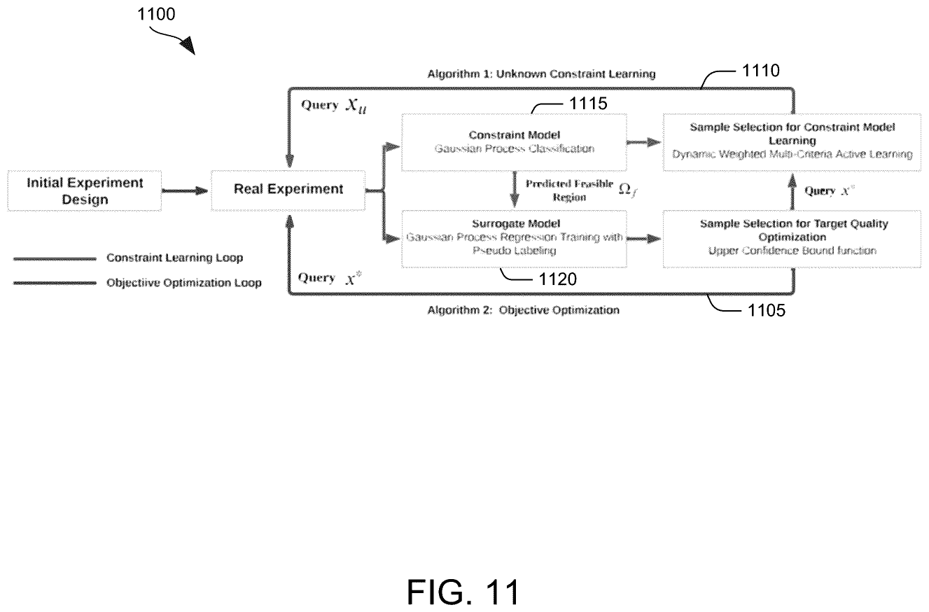

The methods and techniques described herein include a novel experimental design method, or optimization framework 1100, incorporating two feedback loops to address the optimization challenges complicated by unknown feasibility constraints. For the optimization framework 1100, two distinct models may be employed functioning collaboratively. The first model, a constraint model 1115, is utilized to estimate the boundaries of the feasible area within the design space. The second model, a surrogate model 1120, is designed to learn the objective function. As shown in FIG. 11, these two models operate through two separate but interconnected feedback loops, an optimization loop 1105, and an active learning loop 1110. Each loop employs its own strategy for querying new data while the active learning loop utilizes an active sampling strategy based on multiple criteria to explore the boundary for the feasible region, the optimization loop finds the global optimal within a feasible region. Together, the loops collaborate not only to optimize the objective process but also to reveal the relationships between process variables (as inputs) and their resultant properties (as outputs). The optimization framework 1100 is presented in FIG. 11 addresses the following fundamental questions: How to devise a unified framework combining learning about feasibility constraints and understanding the regressive relationships between inputs (process variables) and outputs (properties)? What are the optimal criteria for selecting the most informative samples from unlabeled data, enhancing the precision of constraint estimation for subsequent process optimization? What is the best strategy for selecting samples for experiments to explore the unknown constraint while optimizing the process effectively?

Consider a manufacturing process defined over a predefined design space X⊆R^{D}, where X is the space of a set of process parameters. The process includes a target function ƒ: X→R, which is to be optimized, and a constraint function h:X→Y={0,1}, related to the feasibility of the process which is assumed to be independent of ƒ. For any design point x=[x₁, . . . , x_{D}]^{T}∈X, the process may be feasible when h(x)=0 and infeasible otherwise. For example, ƒ could represent the structure toughness of an additively manufactured part determined by a given vector of design parameters X. Structure toughness is an important property to maximize in the design content for safety and failure tolerance. The variable h may be the boundary to classify the success and failure of structure design given on the same set of design parameters X. To find the optimal process parameters x* within feasible space, which may be regarded as a constrained optimization problem in turn, shown in equation 1.

$$arg {min}_{x ∈ X} f ( x ) \qquad ( 1 )$$

$$s . t . h ( x ) = 0$$

For equation 1, it may be assumed both functions may only be observed or evaluated with costly real experiments or relevant physics-based models. The feasible region Xₛ, the subset of design space with successful experimental settings, is unknown and difficult to obtain owing to the high cost, such as experimental time and cost. The complementary of the feasible region is referred to as the infeasible region such that X_{ƒ}=X\X_{S}. As an example, if there are n samples from the design space denoted by Dₙ={xᵢ, yᵢ, cᵢ}ⁿᵢ₌₁, and \hat{ƒ} and ĥ are our predictors off and h trained with current dataset Dₙ. This work assumes that both ƒ and h follow a Gaussian Process (GP) prior.

$$f ∼ GP ( {μ}_{f} ( \cdot ) ) , {σ}_{f} ( \cdot ) ) \qquad ( 2 )$$

$$h ∼ GP ( {μ}_{h} ( \cdot ) ) , {σ}_{h} ( \cdot ) )$$

For equation 2, where μ·(·) is a mean unction and is a covariance kernel function [57]. GP is a widely used and powerful model for both classification and regression problems.

There are two parts in the active learning loop 1110 in FIG. 11. A constraint model 1115 is adopted to approximate the unknown feasibility constraint, which provides an estimated feasible region varied iteratively for searching the global optimum. In addition, a novel active sampling strategy based on three sampling criteria is designed to refine the constraint learning more effectively. Thereafter, a heuristic-based multi-criteria sampling strategy to identify the most informative samples in a batch mode to refine the approximation of the constraint with the least human effort is described in detail.

A GP classification model may be used to learn the constraint boundary of process feasibility. Given a set of observed experiments, denoted as X=[x₁, x₂, . . . , xₙ] [symbol] , and their corresponding feasibility labels C=[c₁, c₂, . . . , cₙ] [symbol] , a target label feasibility label C∈0, 1 is followed by a Bernoulli distribution. Given observed data X, a goal is to predict target c, at data point x, using the predictive distribution p(c_{*}=0|x_{*}, X, C). An Expectation Propagation algorithm [65] is used to approximate the posterior q(h(x)|X, C) which is non-Gaussian via the Gaussian approximation

$$q ( h ( x ) \vert X , C ) = N ( h ( x ) \vert \hat{μ} ( \cdot ) , \hat{k} ( \cdot , \cdot ) ) \qquad ( 3 )$$

specified by a mean function by \hat{μ}(·) and a positive definite covariance function \hat{k}(·,·). The automatic relevance determination is performed using the radial basis function (RBF) kernel function. The distribution of the latent variable h(x_{*)} corresponding to a new sample x_{*} is

$$p ( {h}_{*} \vert {x}_{*} , X , C ) = \int p ( {h}_{*} \vert {x}_{*} , X , h ) p ( h \vert X , C ) dh \qquad ( 4 )$$

$$where$$

$$h = {[ {h}_{1} , {h}_{2} , … , {h}_{n} ]}^{T} , \qquad ( 5 )$$

$$and then the prediction distribution may be computed via$$

$$p ( {c}_{*} = 0 \vert {x}_{*} , X , C ) = \int Φ ( {h}_{*} ) p ( {h}_{*} \vert {x}_{*} , X , C ) {dh}_{*}$$

Given the predictive probability, the prediction label of x* may be assumed to be the most probable label

$$arg {max}_{{c}_{*}} p ( {c}_{*} \vert {x}_{*} , X , C ) \qquad ( 6 )$$

In each iteration, the constraint model generates a predicted feasible design space Ω_{ƒ} for subsequent unlabeled data selection in the optimization loop. This predicted feasible design space Ω_{ƒ} provided a small but promising region for global optimal searching, and it may also be updated iteratively as more data is labeled in both loops. In addition, the predictive probability may also be utilized to measure the information of unlabeled data to guide data selection in constraint learning loop.

In this active constraint learning loop, three criteria may be adopted jointly to quantify the information carried off each unlabeled sample. In these three criteria, 1) Prediction uncertainty measures the confidence of the current classifier; 2) Representativeness reveals the hidden pattern of unlabeled data, and 3) Diversity is introduced to maximize the information in the selected batch. There are two goals of active sampling via multiple sources of information. The first goal is to improve the optimization efficiency and the secondary goal is to learn the constraint function.

Uncertainty: for unlabeled sample xᵢ, the confidence of prediction is measured by the difference between the prediction probability of the feasible class and the infeasible class, that is:

$$p ( h ( {x}_{i} ) = 0 \vert {x}_{i} ) - p ( h ( {x}_{i} ) = 1 \vert {x}_{i} ) \qquad ( 6 )$$

Larger confidence indicates the classifier has a higher prediction certainty of sample xᵢ, as equation (6) will dominate the prediction result. Additionally, samples with larger confidence are located far away from the boundary of the classifier. Therefore, such a sample is less informative and is less likely to be selected. However, in the active sampling process, it is more relevant to select samples that lie near the decision boundary of two classes, which means such a sample enjoys a higher prediction uncertainty. The uncertainty of prediction Sᵤ(xᵢ) is defined as

$${S}_{u} ( {x}_{i} ) = 1 - \vert p ( h ( {x}_{i} ) = 0 \vert {x}_{i} ) - p ( h ( {x}_{i} ) = 1 \vert {x}_{i} ) \vert \qquad ( 7 )$$

In other words, samples with larger Sᵤ(xᵢ) are more likely to be selected to refine the decision boundary.

Representativeness: The representativeness represents how much similar information one sample xi can carry compared with all remaining unlabeled samples. It is defined as:

$$S r ( {x}_{i} ) = \frac{1}{{N}_{u} - 1} ‖ {x}_{i} - {x}_{j} ‖$$

$${x}_{i} , {x}_{j} ∈ {U}_{s} , i = j$$

where Sᵣ(xᵢ) is the average Euclidean distance between the unlabeled sample xᵢ and all remaining unlabeled samples. The unlabeled sample with the minimum value of Sᵣ(xᵢ) enjoys the highest representativeness. The representativeness is crucial, especially in the initial stage of the optimization process, where prediction uncertainty generated from the constraint model is not perfect owing to the scarcity of labeled data. The representativeness is utilized to explore the decision boundary via a geometrical feature of unlabeled data to compensate for the limitation of purely uncertainty-based strategy.

Diversity: In batch-mode AL, when a batch of unlabeled data is selected for the next iteration, single or both representativeness and uncertainty-based criteria would still not be sufficient to find a group of “informative” samples. To consider redundant information among samples, the diversity of selected samples is introduced to avoid repeatedly selecting samples with high similarity. Diversity term denoted as follows

$${S}_{d} ( {x}_{i} ) = min ‖ {x}_{i} - {X}_{m - 1 , t} ‖ \qquad ( 9 )$$

to measure the dissimilarity between unlabeled samples and selected samples, including labeled samples and selected samples in the current selection batch, X_{m,t} is a set of selected samples in the iteration t and m is a hyperparameter for batch size. For example, in each iteration t, X_{0,t} is the labeled dataset and X_{m-1,t} is the last selected sample in the current batch.

Considering the three criteria described above, a linear aggregated function Q(xᵢ) is proposed to select a batch of samples from the unlabeled dataset, which is defined as follows:

$$Q ( {x}_{i} ) = ( 1 - α - β ) {S}_{u} ( {x}_{i} ) + α {S}_{r} ( {x}_{i} ) + β {S}_{d} ( {x}_{i} ) \qquad ( 10 )$$

where xᵢ∈Us, α, β∈[0, 1] are two non-negative weighted parameters that control the decision-making preference between each criterion. A recent work [52] utilizes a fixed predefined {α, β} set to assign the weights between each criterion. To dynamically control the preference of each criterion in iteration t, another hyperparameter c∈(0, 1] is introduced, such that αt=α0ϵt. The weight parameter αₜ is decayed multiplicatively by ϵ in each iteration t and α0 is predefined as an initial value of αₜ. High α₀ prefer representativeness over uncertainty, and as iteration progresses, Q(xᵢ) shifts from Sᵣ(xᵢ) towards Sᵤ(xᵢ). Low ϵ favors a rapid transition from Sᵣ(xᵢ) to Sᵤ(xᵢ). The reason for this kind of shift may be summarized in two perspectives: i) Owing to the limited observed data in the first couple of iterations, Sᵤ(xᵢ) generated from the constraint model is unreliable as the poor performance of the constraint model. ii) Sᵣ(xᵢ) extracted the geometric information among Uₛ and geometric features should be more informative when a large portion of design space is not explored especially in the initial stage of sampling process.

In addition, Sₖ(·), where k∈{r, u, d}, might be in different scales, so the weight parameter may not be determined directly. Each criterion is normalized as

$${S}_{i} ( X ) = \frac{{S}_{i} ( X ) - min {S}_{i}}{max {S}_{i} - min {S}_{i}}$$

where minimum and maximum of Sₜ(X) for i∈{u, r, d} stand for the minimum and maximum over Uₛ. In the representativeness term, a higher Sᵣ enjoys a lower representativeness, so Sr(xᵢ) is normalized as follows:

$${S}_{r} ( X ) = 1 - \frac{{S}_{i} ( X ) - min {S}_{i}}{max {S}_{i} - min {S}_{i}}$$

With three normalized terms, the integrated acquisition function:

$$Q ( {x}_{i} ) = ( 1 - {α}_{t} - β ) {S}_{u} ( {x}_{i} ) + {α}_{t} {S}_{r} ( {x}_{i} ) ) + β {S}_{d} ( {x}_{i} ) \qquad ( 11 )$$

Compared with the Sᵤ updated after each batch, Sᵣ and S_{d} are extracted from the input size of data, which can be updated after each point is selected. A heuristic way is used to calculate Sr and Sd after one sample is selected in each batch, which means Q(xᵢ) is updated after each selection. The pseudo-code of active sampling via multi-criteria is shown in Algorithm 1.

Algorithm 1 Batch Mode Active Learning for the Unknown Feasibility Constraint

| | Input: Labeled set { [symbol] , [symbol] }, Unlabeled set [symbol] , Batch size m, Weighted parameter set |
|---|---|
| | {α₀, β}, Decaying parameter ϵ, B_{0,t}^{Constraint} ← Ø |
| | Output: B [symbol] ^{Constraint}, selection for constraint model retraining. Ω_{f} predicted feasible |
| | region at the current iteration. |
| 1: | Train ĥ(x) via labeled set { [symbol] , [symbol] }; |
| 2: | Obtain predicted feasible region Ω_{f} from ĥ(x); |
| 3: | Obtain prediction for unlabeled samples [symbol] from ĥ(x); |
| 4: | Calculate S [symbol] (x) using Eq.(7) for unlabeled samples [symbol] ; |
| 5: | for i = 1, 2, . . . , m − 1 do |
| 6: | Calculate S [symbol] (x) using Eq.(8) for unlabeled samples [symbol] ; |
| 7: | Calculate S_{d}(x) using Eq. (9) for unlabeled samples [symbol] ; |
| 8: | x [symbol] ← argmax [symbol] Eq. (11): |
| 9: | [symbol] ← [symbol] \ x [symbol] ; |
| 10: | B_{i,t}^{Constraint} ← B [symbol] ^{Constraint} ∪ x_{i,t} |
| 11: | end for |

[symbol]

indicates data missing or illegible when filed

There are two components in the objective optimization loop 605 in FIG. 6. A surrogate model 620 may be adopted to capture the process-to-quality relationship with uncertainty quantification, which guides the subsequent unlabeled data selection for objective optimization within the estimated feasible design space. Meanwhile, to enhance the learning capability of the surrogate model 620 with limited feasible experimental points, a pseudo-labeling technique via self-training is adopted to label unfeasible designs with predicted target quality. The next sampling point is determined by an acquisition function computed from the prediction of surrogate model training via an augmented dataset.

In this optimization loop, a GP regression may be used as the surrogate process, which captures the relationship between experimental parameters and objective quality. Given on the same set of observed experiments Xₙ, we use Y={y₁, y₂, . . . , yₘ} to represent the corresponding quality outputs of feasible experiments data Xₘ. The complementary of feasible experiments is referred to as the infeasible experiments set such that Xᵤ=Xₙ\Xₘ. The same as (3) in the classification problem, the objective of GP regression is to learn a specific mapping function ƒ(x), which maps an input vector to a label value and a Gaussian prior distribution is placed over ƒ. That is

$$p ( f \vert {X}_{m} ) ∼ N ( {f}^{-} \vert {μ}_{m} ( x ) , {K}_{m} ( x , {x}^{′} ) ) \qquad ( 12 )$$

where μₘ(x) is mean function and Kₘ is an m×m is a covariance matrix and the element of Kₘ is built via a kernel function k(x, x′). The automatic relevance determination is used for the Matern52 kernel function, which is parameterized in terms of the kernel parameters in vector θ

$$k ( {x}_{i} , {x}_{j} \vert θ ) = {σ}_{f}^{2} ( 1 + \sqrt{5} r + \frac{5}{3} {r}^{2} ) exp ( - \sqrt{5} r ) \qquad ( 13 )$$

$$where$$

$$r = \sqrt{{\sum }_{l = 1}^{d} \frac{{( {x}_{il} - {x}_{jl} )}^{2}}{{σ}_{l}^{2}}}$$

In kernel function (13), σ_{ƒ} is a non-negative over scale hyperparameter and σᵢ is a different non-negative length hyperparameter for each predictor. The kernel parameter vector θ=[σ_{ƒ}, σₗ] is unknown initially, and the optimal θ given on observed experiments Xₙ may be estimated by maximizing the marginal likelihood via gradient descent, which are

$$l ( {y}_{m} \vert {X}_{m} , θ ) = - \frac{1}{2} {y}^{T} {K}_{m}^{- 1} y - \frac{1}{2} log \vert {K}_{m} \vert + \frac{1}{2} log 2 π \qquad ( 14 )$$

Given the observed experimental data and optimal parameter vector θ, the prediction distribution of the latent function ƒ_{*} for an unlabeled data x_{*} is

$$p ( f * \vert x * , {X}_{m} {y}_{m} ) = N ( E ( \hat{f} ( x * ) ) , Var ( \hat{f} ( x * ) ) ) \qquad ( 15 )$$

$$where$$

$$μ ( x * ) = k ( x * , {X}_{m} ) {K}_{m}^{- 1} {y}_{m} \qquad ( 16 )$$

$${σ}^{2} ( x * ) = k ( x * , x \text{*)} - k ( x * , {X}_{m} ) {K}_{m}^{- 1} k ( x * , {X}_{m} ) T \qquad ( 17 )$$

However, in real industrial applications, there is the issue of data scarcity, with only a limited number of Xm in the early stage of production. To enhance the surrogate model's learning ability, a pseudo-labeling technique is incorporated using a self-training mechanism [41] to enlarge the training dataset for subsequent iterative selection of unlabeled data. This process involves assigning pseudo-labels obtained via

$${Y}_{u}^{⋀} = k ( {X}_{u} , {X}_{m} ) {K}_{m}^{- 1} {y}_{m} \qquad ( 18 )$$

to observed infeasible samples Xᵤ in each iteration. The prediction of observed infeasible samples may be considered the ground truth even though no target quality exists for observed infeasible samples. Then, the surrogate model may be retrained with the augmented labeled dataset Xₙ and {Y, Y′ᵤ} to guide the selection from in the optimization loop.

With the help of the surrogate model of the target process, an acquisition function is constructed to quantify the most informative candidate samples for objective optimization. Acquisition functions are usually derived from the μ(x) and α(x) generated from the surrogate model, which is easy to compute. This acquisition function allows a balance between exploitation (where the objective μ(x) is high) and exploration (where the objective α(x) is high). Traditionally, the sample with the maximum value of the acquisition function is selected to be labeled in the next iteration. The Upper Confidence Bound (UCB) acquisition function [44] may be used to minimize the target quality of production, the acquisition function is designed as follows:

$$arg {max}_{{x}_{i}} - μ ( {x}_{i} ) + γ σ ( {x}_{i} ) \qquad ( 19 )$$

where γ is a hyperparameter that controls the trade-off between these two terms. Algorithm 2 shows the details of the objective optimization.

Algorithm 2 Samping Strategy for Objective Optimization

| | Input: labeled dataset [symbol] consisting of input, target quality, and feasibility |
|---|---|
| | (x, yᵢ, cᵢ) [symbol] , predicted feasible region space Ω_{f} from Algorithm 1, trade-off |
| | control parameter [symbol] . |
| | Output: [symbol] , Selection in the objective optimization loop |
| 1: | while termination criteria is not meet do |
| 2: | Train [symbol] (x) with labeled feasible dataset (xᵢ, yᵢ\|cᵢ = feasible); |
| 3: | Obtain prediction μᵢ from \hat{f}(x) for labeled in feasible dataset (xᵢ\|cᵢ = infeasible) [symbol] |
| 4: | Retrain [symbol] (x) with (xᵢ, yᵢ\|cᵢ = feasible) and (xᵢ, [symbol] \|cᵢ = infeasible); |
| 5: | Obtain prediction from \hat{f}(x) for Ω_{f}; |
| 6: | x [symbol] = argmax [symbol] Eq. (19); |
| 7: | end while |

[symbol]

indicates data missing or illegible when filed

The methods and techniques described herein introduce the BO-ACL framework (Bayesian Optimization with Active Constraints Learning), a novel approach that synergizes two collaborative loops for querying samples. The BO-ACL framework may optimize an objective quality of interest while simultaneously learning an unknown constraint function, all with minimal human intervention. Additionally, a pool-based active learning process may be used within a finite candidate pool predetermined by experimenters. The initial dataset Dn in Algorithm 3 is selected via the Latin Hypercube Sample (LHS) method. The BO-ACL framework may be terminated when the global optimal sample is found and by expert knowledge.

Algorithm 3 Bayesian Optimization with Active Constraints Learning

| | Input: labeled dataset [symbol] consisting of input, target quality, and feasibility |
|---|---|
| | (x, y [symbol] cᵢ)ᵢ₌₁ [symbol] , unlabeled dataset [symbol] , Weighted parameter set { [symbol] , [symbol] , [symbol] }, Trade-off pa- |
| | rameter [symbol] , Batch size m. |
| 1: | Output: x [symbol] , global optimal feasible sample for target process |
| 2: | while termination criteria is not meet do |
| 3: | Train ĥ(x) with labeled dataset [symbol] ; |
| 4: | Obtain predicted feasible region space Ω_{f} from [symbol] (x) for unlabeled dataset [symbol] ; |
| 5: | Obtain selection x [symbol] in objective optimization via Algorithm 2; |
| 6: | Selected samples Xₛ ← X [symbol] ∪ x [symbol] |
| 7: | Obtain active queries batch B [symbol] ^{Constraint} via Algorithm 1; |
| 8: | X [symbol] ^{batch} ← B [symbol] ^{Constraint} ∪ x [symbol] |
| 9: | Obtain the constraint labels C [symbol] ^{Batch} and target quality Yᵢ^{batch} at Xᵢ^{Batch} via real |
| | experiments; |
| 10: | [symbol] ← [symbol] ∪ {Xᵢ^{batch}, Yᵢ^{batch}, Cᵢ^{batch}}; |
| 11: | [symbol] ← [symbol] \ Xᵢ^{batch}; |
| 12: | end while |

[symbol]

indicates data missing or illegible when filed

Unlike traditional batch model sampling strategies, BO-ACL implements a sequential sampling approach within each batch. This method ensures that each selection impacts subsequent choices within the same iteration. In each iteration, among M selections, the first sample is chosen using Algorithm 2, followed by M−1 samples selected sequentially through Algorithm 1. The optimization and active learning loop influence each other's selection processes. For a detailed understanding, the pseudo-code of the BO-ACL framework is outlined in Algorithm 3.

The efficacy and performance of the proposed framework may be evaluated via two 2-D synthetic datasets: Simulation (1): 2D three-hump camel function on the domain [−2, 2]×[−2, 2], where the function is

$$f ( x ) = 2 {x}_{1}^{2} - 1.05 {x}_{1}^{4} + \frac{{x}_{1}^{6}}{6} + {x}_{1} {x}_{2} + {x}_{2}^{2} \qquad ( 20 )$$

The global minimum of this function is ƒ(x*)=0 at x*=(0, 0). There are four disjoint infeasible regions, including four squares with dimensions of 1.2 for all squares. Simulation (2): 2D function as follow:

$$g ( x ) = {x}_{1}^{2} - sin ( 4 {x}_{2}^{2} ) \qquad ( 21 )$$

on the domain [−1, 1]×[−1, 1]. The samples may be feasible when x²−x¹≤0. The global optimum of g(x) with constraint is ƒ(x*)=1 at x*=(0, 0). Unlike the 2D three-hump camel function, the global optimum in the second function with constraint is located in the feasibility boundary. Two representative datasets may be used to test the performance of the proposed framework.

The BO-ACL framework is designed to optimize the target objective function with the least human effort following the feasibility constraint. The convergence of the BO-ACL framework is evaluated to the global optimum. The rt are used to evaluate the convergence rate, which is defined as follows:

$${r}_{t} = min \{ {y}_{t} \} - f ( {x}^{⋆} )$$

where Yₜ is the output of labeled feasible samples at iteration t, ƒ(x*) is the global optimum of target surrogate function. Our framework is compared with several baseline frameworks with the same batch size m as follows: (1) Random Search (RS), which randomly selects m samples in each iteration; (2) Constrained Bayesian Optimization (CBO), a BayesOpt method with constrained acquisition function for unknown constraints [47]; (3) pBO-2GP-3B, a parallel BayeOpt framework with three acquisition functions [63].

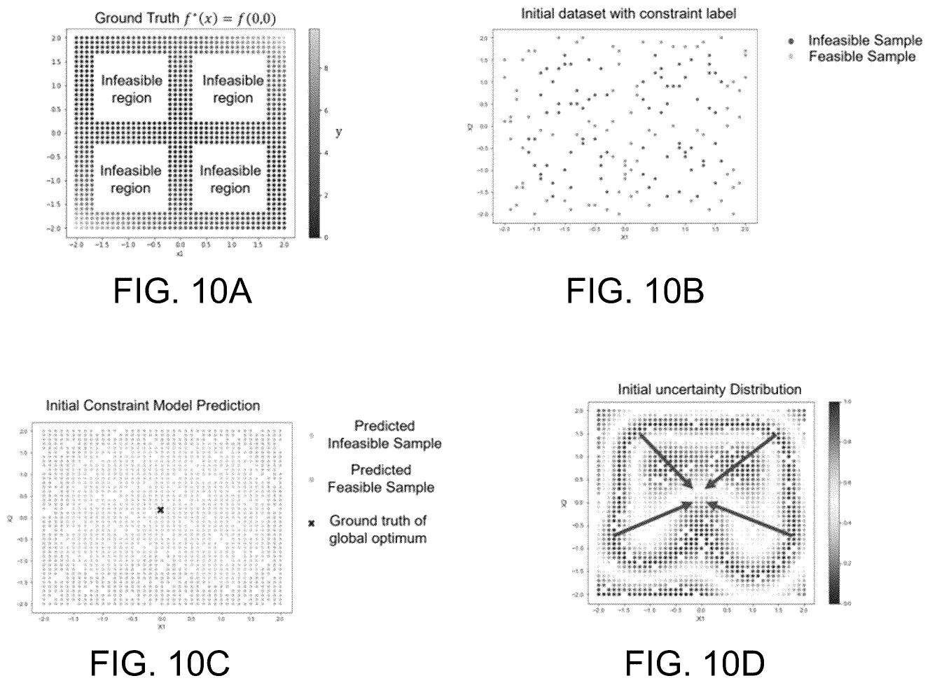

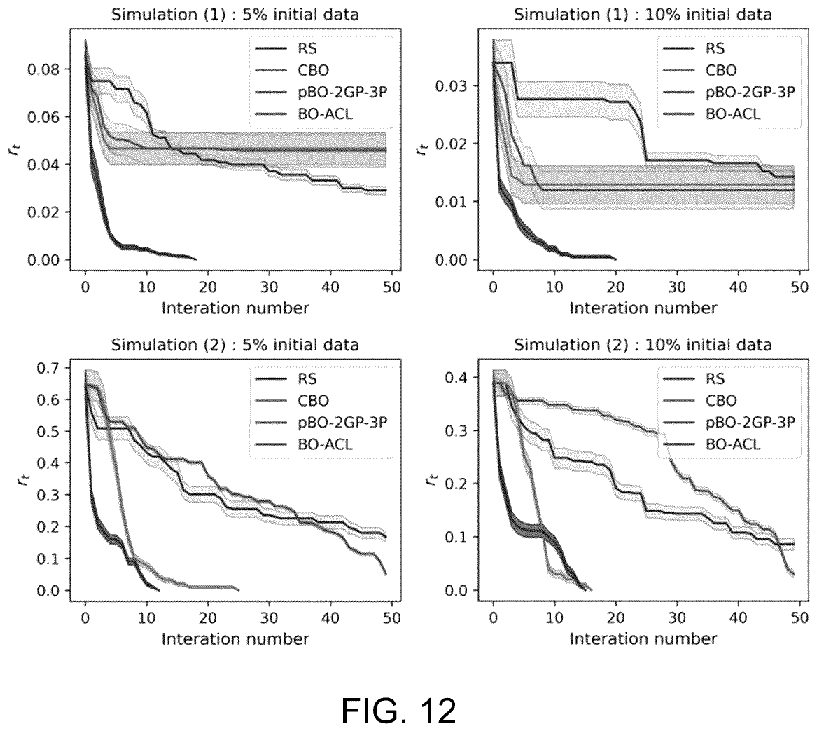

Frameworks CBO and pBO-2GP-3B may be chosen for the next part to study the effectiveness of the proposed framework. To further study the sensitivity to the initial size of labeled data, two different levels are set of initially labeled ratio: 5% and 10%. The iterative process may be terminated when rₜ equals 0, and set a maximum value of process iteration t. The optimization process may be terminated when t equals 50, which means the method does not find the global optimal within 50 iterations owing to the problems identified in FIGS. 10A-10D. For a fair comparison, the initial data is generated via the LHS method over 20 runs, and the same batch size is set up for comparison. A batch size equal to 3 is set up because there are three acquisition functions in the pBO-2GP-3B, and three is the least batch number. It is worth mentioning that there is a weighted parameter set {α₀, β, ϵ} in Algorithm 1. The effect of changes in weight parameters may be investigated on the results in the industrial case study discussed below. In this part, initialize weight parameter set {α₀=0.7, β=0.2, ϵ=0.8} in Simulation (1) and weight parameter set {α₀=0.6, β=0.3, ϵ=0.7} in Simulation (2) with a lower α₀ and ϵ because the overall data volume of Simulation (2) is much smaller than Simulation (1). FIG. 12 depicts rt of different frameworks versus optimization iteration number. The results demonstrate that the BO-ACL framework outperforms the baseline frameworks in the following two aspects, regardless of the initial label ratio.

Convergence speed: the BO-ACL framework significantly improves the average convergence speed in 20 runs in both cases. Especially in the Simulation (1), the proposed method tackles the problem described above. If the global optimum is located in the boundary of constraint, the CBO method can help identify the global optimum but wastes a lot of effort when there is a limited number of initial data.

Performance Stability: Compared with all baseline frameworks, the BO-ACL framework shows a more stable performance in terms of variations of rₜ within 20 runs. Owing to the problem shown in FIGS. 10A-10D, the variance of rₜ in Simulation (1) will be a constant if the constraint model misclassifies the global optimum as an infeasible sample. The variance of rₜ in each iteration for Simulation (2) is much smaller than in Simulation (1).

A learning constraint is a secondary goal, and understanding the accuracy of the feasibility constraint learned through the GP classification is crucial. These feasibility constraints, initially unknown, become progressively clearer through an iterative optimization process. The ACL loop utilizes a heuristic multi-criteria sampling strategy to facilitate learning the constraint boundary. Meanwhile, the samples selected from the objective optimization loop also influence the performance of constraint estimation. To validate the effectiveness of the constraint estimation approach, an evaluation process is used that are widely adopted in previous research on pool-based AL.

All labeled samples are used as training data in a pool-based AL [66]). After each iteration, the Macro F1-score is computed as the performance measurement. The goal of pool-based AL is to create a classifier that accurately labels all candidates in the pool. However, various sampling strategies result in different labeled samples. To ensure a fair comparison, the F1-score is computed using all samples in the pool, including the Dₙ labeled data with their ground truth and the remaining N−Dₙ unlabeled samples with predictions from the constraint model. Additionally, for consistent validation, each optimization framework terminates at the same iteration, specifically the average convergence iteration of the proposed framework.

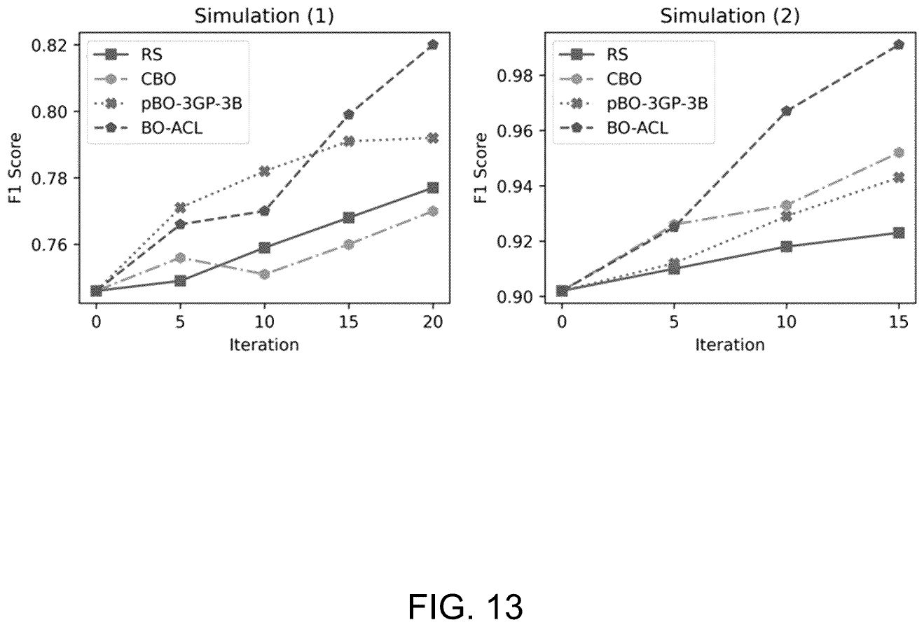

FIG. 13 shows the average F1-score of BO-ACL and the baseline methods for each simulation study. The results demonstrate that the proposed framework outperforms the baseline methods. However, compared with benchmark methods, the proposed method performance is worse in the first few iterations and achieves the best performance later. By contrast, as shown in FIG. 12, the rₜ decreases dramatically in the first few iterations. It shows that the framework is not just a simple combination of active learning and Bayesian optimization. The AL loop and optimization process are designed to work collaboratively and benefit each other from iteration to iteration.

A case study for industrial application may be implemented and validated for the proposed method for the 2D material synthesis process via the chemical vapor deposition (CVD) method and demonstrated the effectiveness of the BO-ACL framework. Compared with other AL-assisted optimization frameworks, the proposed framework achieves the best performance: fast convergence to identify the parameter setting with the best target quality from a small initial labeled dataset and high constraint estimation accuracy.

Molybdenum disulfide (MoS₂) is a typical two-dimensional transition metal dichalcogenide (2D-TMDs), enabling next-generation semiconductors and future quantum applications. Chemical vapor deposition that starts with metal-organic precursors dominates the growth studies. The material synthesis process via the CVD method requires precise adjustment of several interrelated experimental parameters to yield high-quality monolayer 2D-TMDs. Given the constraints of budget and time, material scientists aim to minimize experimental trials to efficiently discern the optimal parameter settings for successful MoS₂ growth and high-quality sample production.

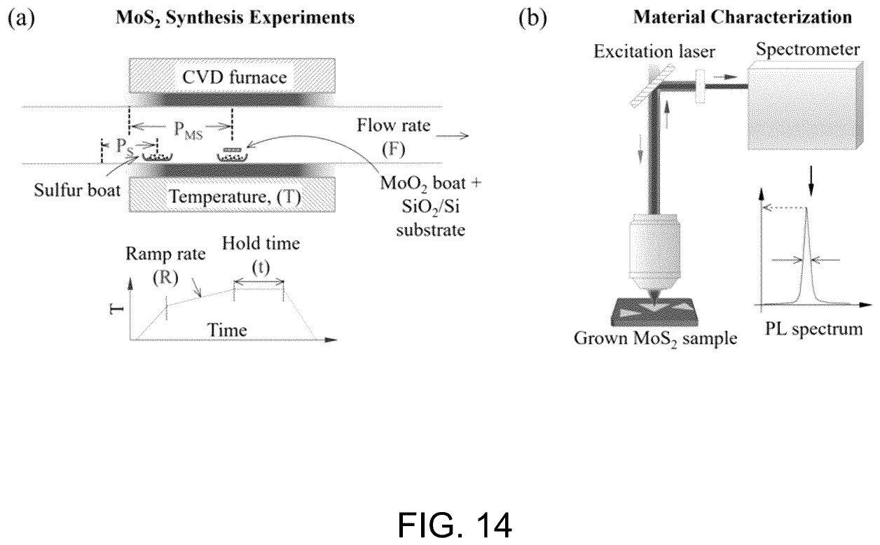

In this work, a single heat source thermal CVD furnace was used to perform the experiments, and FIG. 14 shows the specific layout of the CVD furnace. Following the furnace setting, five physically correlated experimental variables working together form a 5-dimensional design space with 384 points for process analysis. Photoluminescence spectra (PL, excited by 473 nm laser) of MoS₂ were used to characterize the grown samples. A minimum PL intensity of 0.05 (a.u., normalized by silicon Raman peak at 521 cm⁻¹) was used to classify successful from failed growth. The fitted A-exciton linewidth σ_{A} (meV, obtained by Lorentzian function fits) was used to measure sample quality [50]. Recent work [62] unveils the relationship between synthesis parameters and the success of experiments, which is valuable for material scientists to set up experimental conditions with a high success rate. A small value of linewidth represents a high quality of materials.

The pool-based scenario is adopted in which 384 samples in the candidate pool uniformly spread out the design space. Out of a total of 384 samples, 204 were successful design conditions, while 180 designs failed. The minimum value of the linewidth of successful samples is 0.03789 meV. For the initial design, orthogonal arrays with 48 samples generated by the Taguchi method are used as the initial dataset. Considering the variability in the initial design and the small size of the initial dataset, 24 samples are chosen and 36 samples randomly chosen from orthogonal arrays independently and replicated the experiments 20 times.

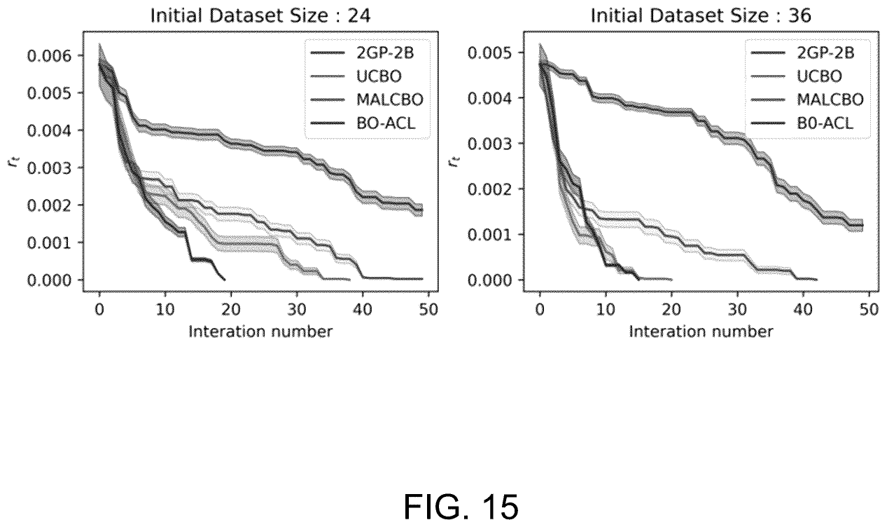

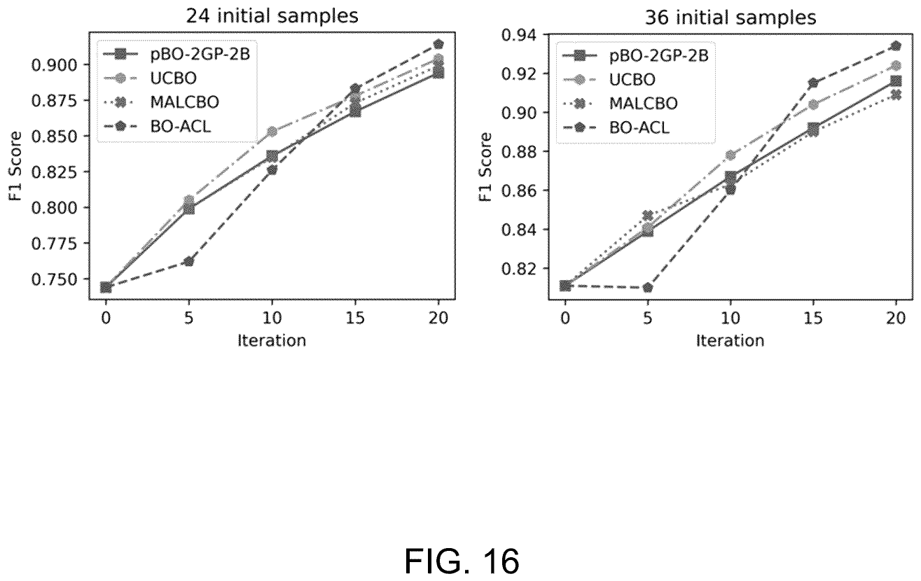

In this real-world case study, the framework performance is evaluated by comparing it with baseline frameworks: (i) pBO-2GP-2P, the framework [63] proposed with only two acquisition functions. (ii) UCBO, the framework we proposed with an uncertainty-based sampling strategy in the AL loop. (iii) MALCBO, the framework proposed with a multi-criteria sampling strategy considering uncertainty and diversity with a constant weighted parameter. For a fair comparison, baseline frameworks start from the same initial dataset with the proposed method, which means the r₀ is the same within all frameworks given on the same initial dataset. Three samples are selected in each iteration, where two queries are generated from the ACL loop, and one is generated from the objective optimization loop. The iterative optimization process will be terminated when the global optimal sample is selected. The r, under different iterations and frameworks with different initial dataset sizes are shown in FIG. 15. The proposed framework shows superior performance over the baselines. The proposed framework may find the global optimal sample with an average of 20 iterations, no matter the size of the initial dataset. The sampling strategy is terminated at the 20th iteration, which is the average number of iterations needed to find the global optimum. FIG. 16 depicts the accuracy comparison of constraint estimation via different methods. The proposed BO-ACL method shows the best constraint estimation results even though the estimation performance is not better than other baseline methods in the first couple of iterations.

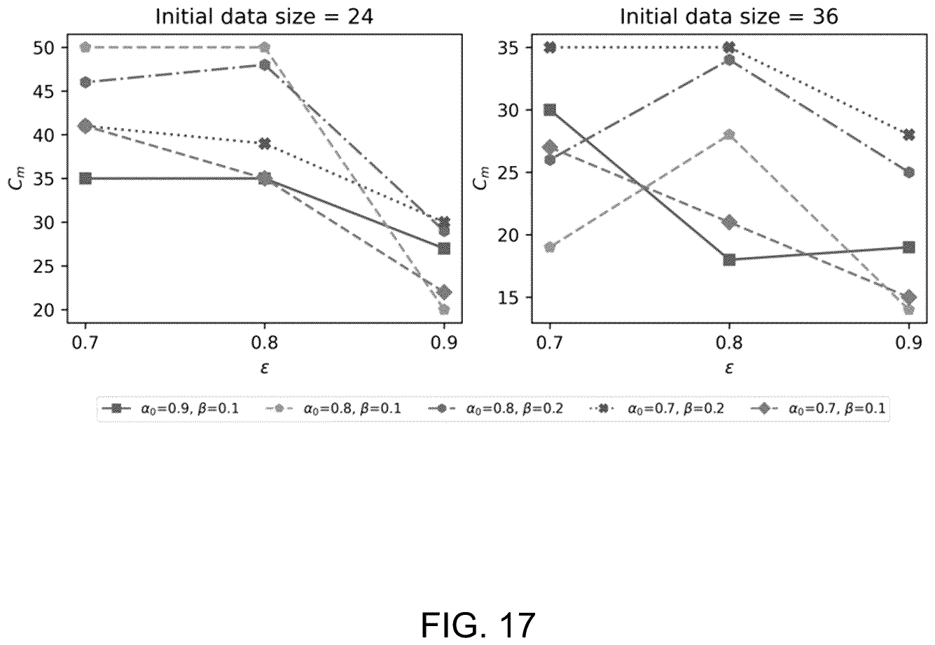

The effect of changes in weight parameters on the optimization result may be investigated. In a weighted parameter set {α₀, β, ϵ}, three parameters are chosen to distribute the weights assigned on each criterion in the active learning process, i.e., α₀>0, β>0, 0<ϵ<1, α₀+β≤1. For example, when α₀=0, the active learning process considers both uncertainty and diversity and by contrast, when α₀+β=1, the active learning process considers both representativeness and diversity. Generally, the weighted parameter set is predefined by engineers considering the dimension of features and the size of the overall design space. In addition, c controls the shifting rate for flavors from representativeness to uncertainty. Here, a lower value of c represents a quick shift. In this sensitivity analysis, the same initial dataset from above is used and set the batch size to 3. Different weight parameters are considered in this case study. For this, Cₘ is used, which represents the maximum number of iterations that must be used to capture the global optimum and evaluate the convergence speed with different weighted parameters. FIG. 17 shows the performance of different weight parameters.

In this industrial case study, three levels of ϵ={0.9, 0.8, 0.7} are set up to control the shifting focus speed from the representativeness criterion to the uncertainty. The convergence speed of objective quality optimization is the best with ϵ=0.9, which means the focus of the representativeness term should not shift too quickly to the uncertainty term. It highlights the significance of the representativeness term described herein. Similarly, three levels of α₀={0.9, 0.8, 0.7} are set up to test the influence of the initial weights on the representativeness term and uncertainty term. The higher the value of α₀, the higher the convergence speed. FIG. 17 also indicates the need to assign a higher value of α₀ when there are fewer initial datasets. In addition, the performance is better with β=0.1. This also provides a guide on how to set up the weight parameter first. The weight parameter should be chosen according to the complexity of the dataset. The multi-criteria-based sampling strategy in the AL process could be more informative in the scenario where the complexity of the dataset is high.

While quick convergence is desirable, it does not necessarily ensure accurate constraint estimation. The weight parameters influence both the speed of convergence and the quality of constraint estimation. The evaluation methodology described herein, terminating the iterative process at the 20th iteration and calculating the F1-score to assess performance. Table 1 presents the framework's F1-scores for different parameter settings. The results indicate that the performance in constraint estimation remains relatively stable across various sets of weight parameters.

The novel parameter design framework described herein for the constrained manufacturing process focused on addressing the main challenges of optimizing the process and estimating the constraint simultaneously with the least human effort. The major contribution of this study lies in the fused AL and BayesOpt sampling in a unified framework that works collaboratively in an iterative process (i) to learn the feasibility of experimental design and (ii) optimize the target quality of process with minimal experiments efforts.

A generic sampling framework is presented for integrating AL and BayesOpt, in which AL performs as a feasible region estimator to help the optimization process search for the global optimum in a relatively reliable region. With a limited volume of the initial dataset, the proposed framework can still efficiently use minimal human labeling efforts to discover the optimal experimental design. A heuristic sampling strategy is used in the AL loop based on multiple measurements. With the multi-criteria active sampling, the search scope for the optimization process will be updated with iterations, and a better feasibility estimation will be obtained simultaneously. A dynamic weighted mechanism is designed to distribute the focus on each measurement to improve the optimization and prediction accuracy. The proposed framework and algorithms are verified and validated using both synthetic datasets and a real-world material synthesis dataset to show superior optimization performance with minimal experimental cost.

TABLE 1
F1 score with different weigh parameters

| ε = 0.9 | |
|---|---|
| 24 | 36 |

| Weight Parameter | Mean | Std | Mean | Std |
|---|---|---|---|---|
| α₀ = 0.8, β = 0.1 | 0.914 | 0.017 | 0.934 | 0.010 |
| α₀ = 0.9, β = 0.1 | 0.912 | 0.015 | 0.929 | 0.030 |
| α₀ = 0.7, β = 0.1 | 0.910 | 0.020 | 0.928 | 0.026 |
| α₀ = 0.8, β = 0.2 | 0.910 | 0.17 | 0.926 | 0.016 |
| α₀ = 0.8, β = 0.2 | 0.907 | 0.016 | 0.924 | 0.016 |

As used herein, “consisting essentially of” allows the inclusion of materials or steps that do not materially affect the basic and novel characteristics of the claim. Any recitation herein of the term “comprising”, particularly in a description of components of a composition or in a description of elements of a device, can be exchanged with “consisting essentially of” or “consisting of”.

While the present invention has been described in conjunction with certain preferred embodiments, one of ordinary skill, after reading the foregoing specification, will be able to effect various changes, substitutions of equivalents, and other alterations to the compositions and methods set forth herein.

### REFERENCES

[1] X. Li, W. Cai, J. An, S. Kim, J. Nah, D. Yang, R. Piner, A. Velamakanni, I. Jung, E. Tutuc, S. K. Banerjee, L. Colombo, R. S. Ruoff, Science 2009, 324, 1312.
[2] Y.-H. Lee, X.-Q. Zhang, W. Zhang, M.-T. Chang, C.-T. Lin, K.-D. Chang, Y.-C. Yu, J. T.-W. Wang, C.-S. Chang, L.-J. Li, T.-W. Lin, Advanced Materials 2012, 24, 2320.
[3] Y. Shi, C. Hamsen, X. Jia, K. K. Kim, A. Reina, M. Hofmann, A. L. Hsu, K. Zhang, H. Li, Z.-Y. Juang, Mildred. S. Dresselhaus, L.-J. Li, J. Kong, Nano Lett. 2010, 10, 4134.
[4] B. Ozturk, A. de-Luna-Bugallo, E. Panaitescu, A. N. Chiaramonti, F. Liu, A. Vargas, X. Jiang, N. Kharche, O. Yavuzcetin, M. Alnaji, M. J. Ford, J. Lok, Y. Zhao, N. King, N. K. Dhar, M. Dubey, S. K. Nay ak, S. Sridhar, S. Kar, Science Advances 2015, 1, e1500094.
[5] S. M. Kim, A. Hsu, P. T. Araujo, Y.-H. Lee, T. Palacios, M. Dresselhaus, J.-C. Idrobo, K. K. Kim, J. Kong, Nano Lett. 2013, 13, 933.
[6] A. Vargas, F. Liu, C. Lane, D. Rubin, I. Bilgin, Z. Hennighausen, M. DeCapua, A. Bansil, S. Kar, Science Advances 2017, 3, e1601741.
[7] S. H. Choi, S. J. Yun, Y. S. Won, C. S. Oh, S. M. Kim, K. K. Kim, Y. H. Lee, Nat Commun 2022, 13, 1484.
[8] Y. Han, B. Tang, L. Wang, H. Bao, Y. Lu, C. Guan, L. Zhang, M. Le, Z. Liu, M. Wu, ACS Nano 2020, 14, 14761.
[9] T. Lookman, P. V. Balachandran, D. Xue, R. Yuan, npj ComputMater 2019, 5, 21.
[10] P. M. Attia, A. Grover, N. Jin, K. A. Severson, T. M. Markov, Y.-H. Liao, M. H. Chen, B. Cheong, N. Perkins, Z. Yang, P. K. Herring, M. Aykol, S. J. Harris, R. D. Braatz, S. Ermon, W. C. Chueh, Nature 2020, 578, 397.
[11] V. L. Deringer, A. P. Bartók, N. Bernstein, D. M. Wilkins, M. Ceriotti, G. Csinyi, Chem. Rev. 2021, 121, 10073.
[12] J. L. Beckham, K. M. Wyss, Y. Xie, E. A. McHugh, J. T. Li, P. A. Advincula, W. Chen, J. Lin, J. M. Tour, Advanced Materials 2022, 34, 2106506.
[13] J. Chang, P. Nikolaev, J. Carpena-Núñez, R. Rao, K. Decker, A. E. Islam, J. Kim, M. A. Pitt, J. I. Myung, B. Maruyama, Sci Rep 2020, 10, 9040.
[14] C. Lampe, I. Kouroudis, M. Harth, S. Martin, A. Gagliardi, A. S. Urban, Advanced Materials 2023, 35, 2208772.
[15] A. Costine, P. Delsa, T. Li, P. Reinke, P. V. Balachandran, Journal of Applied Physics 2020, 128, 235303.
[16] B. Tang, Y. Lu, J. Zhou, T. Chouhan, H. Wang, P. Golani, M. Xu, Q. Xu, C. Guan, Z. Liu, Materials Today 2020, 41, 72.
[17] K. Tanaka, K. Hachiya, W. Zhang, K. Matsuda, Y. Miyauchi, ACS Nano 2019, 13, 12687.
[18] P. Priya, T. C. Nguyen, A. Saxena, N. R. Aluru, ACS Nano 2022, 16, 1929.
[19] E. Vargo, J. C. Dahl, K. M. Evans, T. Khan, P. Alivisatos, T. Xu, Advanced Materials 2022, 34, 2203168.
[20] M. Meuwly, Chem. Rev. 2021, 121, 10218.
[21] S. Greenhill, S. Rana, S. Gupta, P. Vellanki, S. Venkatesh, IEEE Access 2020, 8, 13937.
[22] D. Khatamsaz, B. Vela, P. Singh, D. D. Johnson, D. Allaire, R. Arróyave, npj Comput Mater 2023, 9, 49.
[23] D. Hejazi, R. Tan, N. Kari Rezapour, M. Mojtabavi, M. Wanunu, S. Kar, ACS Appl. Nano Mater. 2021, 4, 2583.
[24] A. McCreary, A. Berkdemir, J. Wang, M. A. Nguyen, A. L. Elias, N. Perea-López, K. Fujisawa, B. Kabius, V. Carozo, D. A. Cullen, T. E. Mallouk, J. Zhu, M. Terrones, Journal of Materials Research 2016, 31, 931.
[25] L. Xu, L. Zhao, Y. Wang, M. Zou, Q. Zhang, A. Cao, Nano Res. 2019, 12, 1619.
[26] K. F. Mak, K. He, C. Lee, G. H. Lee, J. Hone, T. F. Heinz, J. Shan, Nature Mater 2013, 12, 207.
[27] H. Zhang, M. Chhowalla, Z. Liu, Chem. Soc. Rev. 2018, 47, 3015.
[28] Y. Lin, X. Ling, L. Yu, S. Huang, A. L. Hsu, Y.-H. Lee, J. Kong, M. S. Dresselhaus, T. Palacios, Nano Lett. 2014, 14, 5569.
[29] J. W. Christopher, B. B. Goldberg, A. K. Swan, Sci Rep 2017, 7, 14062.
[30] I. Bilgin, F. Liu, A. Vargas, A. Winchester, M. K. L. Man, M. Upmanyu, K. M. Dani, G. Gupta, S. Talapatra, A. D. Mohite, S. Kar, ACS Nano 2015, 9, 8822.
[31] F. Cadiz, E. Courtade, C. Robert, G. Wang, Y. Shen, H. Cai, T. Taniguchi, K. Watanabe, H. Carrere, D. Lagarde, M. Manca, T. Amand, P. Renucci, S. Tongay, X. Marie, B. Urbaszek, Phys. Rev. X 2017, 7, 021026.
[32] D. Sercombe, S. Schwarz, O. D. Pozo-Zamudio, F. Liu, B. J. Robinson, E. A. Chekhovich, I. I. Tartakovskii, O. Kolosov, A. I. Tartakovskii, Sci Rep 2013, 3, 3489.
[33] L. Sun, X. Zhang, F. Liu, Y. Shen, X. Fan, S. Zheng, J. T. L. Thong, Z. Liu, S. A. Yang, H. Y. Yang, Sci Rep 2017, 7, 16714.
[34] J. Pandey, A. Soni, Applied Surface Science 2019, 463, 52.
[35] D. Bergmann, K. Graichen, in 2020 59th IEEE Conference on Decision and Control (CDC), IEEE, Jeju, Korea (South), 2020, pp. 3592-3597.
[36] M. A. Gelbart, J. Snoek, R. P. Adams, 2014, DOI 10.48550/ARXIV.1403.5607.
[37] D. Zhou, O. Bousquet, T. Lal, J. Weston, B. Scholkopf, in Advances in Neural Information Processing Systems (Eds.: S. Thrun, L. Saul, B. Schölkopf), MIT Press, 2003.
[38] V.-L. Nguyen, M. H. Shaker, E. Hüllermeier, Mach Learn 2022, 111, 89.
[39] Q. Liang, A. E. Gongora, Z. Ren, A. Tiihonen, Z. Liu, S. Sun, J. R. Deneault, D. Bash, F. Mekki-Berrada, S. A. Khan, K. Hippalgaonkar, B. Maruyama, K. A. Brown, J. Fisher III, T. Buonassisi, npj Comput Mater 2021, 7, 188.
[40] Y. K. Wakabayashi, T. Otsuka, Y. Krockenberger, H. Sawada, Y. Taniyasu, H. Yamamoto, npj Comput Mater 2022, 8, 180.
[41] Amini, M.-R., Feofanov, V., Pauletto, L., Devijver, E., and Maximov, Y. (2022). Self-training: A survey. arXiv preprint arXiv:2202.12040.
[42] Bukkapatnam, S. T. (2023). Autonomous materials discovery and manufacturing (amdm): A review and perspectives. IISE Transactions, 55(1):75-93.
[43] Burbidge, R., Rowland, J. J., and King, R. D. (2007). Active learning for regression based on query by committee. In International conference on intelligent data engineering and automated learning, pages 209-218. Springer.
[44] Contal, E., Buffoni, D., Robicquet, A., and Vayatis, N. (2013). Parallel gaussian process optimization with upper confidence bound and pure exploration. In Machine Learning and Knowledge Discovery in Databases: European Conference, ECML PKDD 2013, Prague, Czech Republic, Sep. 23-27, 2013, Proceedings, Part 113, pages 225-240. Springer.
[45] Costine, A., Delsa, P., Li, T., Reinke, P., and Balachandran, P. V. (2020). Data-driven assessment of chemical vapor deposition grown mos2 monolayer thin films. Journal of Applied Physics, 128(23).
[46] Du, B., Wang, Z., Zhang, L., Zhang, L., Liu, W., Shen, J., and Tao, D. (2015). Exploring representativeness and informativeness for active learning. IEEE transactions on cybernetics, 47(1):14-26.
[47] Gardner, J. R., Kusner, M. J., Xu, Z. E., Weinberger, K. Q., and Cunningham, J. P. (2014). Bayesian optimization with inequality constraints. In ICML, volume 2014, pages 937-945.
[48] Gelbart, M. A., Snoek, J., and Adams, R. P. (2014). Bayesian optimization with unknown constraints. In 30th Conference on Uncertainty in Artificial Intelligence, UAI 2014, pages 250-259. AUAI Press.
[49] Guidetti, X., Rupenyan, A., Fassl, L., Nabavi, M., and Lygeros, J. (2021). Plasma spray process parameters configuration using sample-efficient batch Bayesian optimization. In 2021 IEEE 17th International Conference on Automation Science and Engineering (CASE), pages 31-38. IEEE.
[50] Hejazi, D., Tan, R., Kari Rezapour, N., Mojtabavi, M., Wanunu, M., and Kar, S. (2021). Mos2 nanosheets with narrowest excitonic line widths grown by flowless direct heating of bulk powders: Implications for sensing and detection. ACS Applied Nano Materials, 4(3):2583-2593.
[51] Huang, S.-J., Jin, R., and Zhou, Z.-H. (2010). Active learning by querying informative and representative examples. Advances in neural information processing systems, 23.
[52] Kee, S., Del Castillo, E., and Runger, G. (2018). Query-by-committee improvement with diversity and density in batch active learning. Information Sciences, 454:401-418.
[53] Lam, R. and Willcox, K. (2017). Lookahead Bayesian optimization with inequality constraints. Advances in Neural Information Processing Systems, 30.
[54] Lee, C., Wang, X., Wu, J., and Yue, X. (2022). Failure-averse active learning for physics-constrained systems. IEEE Transactions on Automation Science and Engineering.
[55] Liu, Z., Jiang, X., Luo, H., Fang, W., Liu, J., and Wu, D. (2021). Pool-based unsupervised active learning for regression using iterative representativeness-diversity maximization (irdm). Pattern Recognition Letters, 142:11-19.
[56] Park, S. H. and Kim, S. B. (2019). Active semi-supervised learning with multiple complementary information. Expert Systems with Applications, 126:30-40.
[57] Rasmussen, C. E. (2003). Gaussian processes in machine learning.
[58] Schonlau, M., Welch, W. J., and Jones, D. R. (1998). Global versus local search in constrained optimization of computer models. Lecture notes-monograph series, pages 11-25.
[59] Settles, B. (2009). Active learning literature survey. University of Wisconsin-Madison Department of Computer Sciences.
[60] Shim, J., Kang, S., and Cho, S. (2021). Active cluster annotation for wafer map pattern classification in semiconductor manufacturing. Expert Systems with Applications, 183:115429.
[61] Sui, Y., Zhuang, V., Burdick, J., and Yue, Y. (2018). Stagewise safe Bayesian optimization with gaussian processes. In International conference on machine learning, pages 4781-4789. PMLR.
[62] Tang, B., Lu, Y., Zhou, J., Chouhan, T., Wang, H., Golani, P., Xu, M., Xu, Q., Guan, C., and Liu, Z. (2020). Machine learning-guided synthesis of advanced inorganic materials. Materials Today, 41:72-80.
[63] Tran, A., Sun, J., Furlan, J. M., Pagalthivarthi, K. V., Visintainer, R. J., and Wang, Y. (2019). pbo-2gp-3b: A batch parallel known/unknown constrained Bayesian optimization with feasibility classification and its applications in computational fluid dynamics. Computer Methods in Applied Mechanics and Engineering, 347:827-852.
[64] Wang, G., Hwang, J.-N., Rose, C., and Wallace, F. (2017). Uncertainty sampling based active learning with diversity constraint by sparse selection. In 2017 IEEE 19th International Workshop on Multimedia Signal Processing (MMSP), pages 1-6. IEEE.
[65] Williams, C. K. and Rasmussen, C. E. (2006). Gaussian processes for machine learning, volume 2. MIT press Cambridge, MA.
[66] Wu, D. (2018). Pool-based sequential active learning for regression. IEEE transactions on neural networks and learning systems, 30(5):1348-1359.
[67] Wu, D., Lin, C.-T., and Huang, J. (2019). Active learning for regression using greedy sampling. Information Sciences, 474:90-105.

What is claimed is:

1. A computer-implemented method for optimizing a fabrication process, the method comprising:
receiving process data, wherein the process data includes a set of data points, each data point representing a set of one or more process parameters for the fabrication process and corresponding results for the fabrication process, wherein the set of data points are sampled from a defined design space of process parameter values, and wherein the results include a success indicator representing a successful fabrication and a quality metric representing a measurement of the fabrication process for each set of process parameters;
determining a feasible region from the process data and using a classification model, wherein the feasible region represents a portion of the defined design space with data points corresponding to successful fabrications;
determining, using a regression model and the feasible region, predicted values for each data point in the feasible region, wherein the predicted values represent a mean value of the quality metric and a variance value for each data point in the feasible region;
calculating a score for each data point in the feasible region, wherein the score is a weighted average of the mean value and the variance value from the predicted values of the corresponding data point;
selecting one or more recommended data points, each recommended data point representing a recommended set of process parameters, based on a ranking of the data points in the feasible region corresponding to the score of each data point;
receiving experimental results corresponding to the one or more recommended data points, each experimental result including a quality metric;
determining a set of one or more optimal data points from the recommended data points based on the corresponding quality metric satisfying a predetermined range or threshold for the quality metric; and
outputting the set of one or more optimal data points and/or corresponding one or more optimal process parameters.

2. The computer implemented method of claim 1, wherein prior to receiving the process data, the method further comprises:
receiving initial data, wherein the initial data includes a set of one or more initial data points and corresponding results for the fabrication process, each initial data point representing a set of one or more process parameters for the fabrication process and wherein the results include a success indicator and a quality metric representing a measurement of the fabrication process for each set of process parameters, wherein the success indicator indicates success or failure of the fabrication in satisfying the predetermined range or threshold for the quality metric;
determining an initial feasible region from the initial data and using the classification model, wherein the feasible region represents the portion of the defined design space with data points corresponding to successful fabrications;
determining, using the regression model and the feasible region, initial predicted values for each data point in the initial feasible region, wherein the initial predicted values represent an initial mean value of the quality metric and an initial variance value for each data point in the initial feasible region;
calculating an initial score for each data point in the initial feasible region, wherein the initial score is a weighted average of the initial mean value and the initial variance value from the initial predicted values of the corresponding data point;
selecting one or more initial recommended data points based on a ranking of the data points in the initial feasible region corresponding to the initial score of each data point;
receiving initial experimental results corresponding to the one or more initial recommended data points, each initial experimental result including a quality metric; and
setting the initial recommended data points and corresponding initial experimental results as the process data.

3. The computer implemented method of claim 2, further comprising:
determining, using the classification model, a probability value for each data point of the defined design space, the probability value representing a probability of success for the fabrication process;
calculating, based on the probability value, an uncertainty value for each data point of the defined design space;
selecting one or more data points from the defined design space, as one or more uncertain data points, based on a ranking of the data points of the defined design space corresponding to the uncertainty value of each data point; and
adding the one or more uncertain data points to the initial recommended data points; and
wherein the one or more uncertain data points are included in the initial recommended data points for the performance of the fabrication process.

4. The computer implemented method of claim 2, further comprising:
selecting one or more variance data points based on a ranking of the data points in the initial feasible region corresponding to the variance value from the initial predication values of each data point;
adding the one or more variance data points to the initial recommended data points; and
wherein the one or more variance data points are included in the initial recommended data points for the performance of the fabrication process.

5. The computer implemented method of claim 2, further comprising:
processing the initial data with the classification model to further train the classification model; and/or
processing the initial data with the regression model to further train the regression model.

6. The computer implemented method of claim 1, wherein determining the feasible region further comprises:
determining, using the classification model, a probability value for each data point of the defined design space, the probability value representing a probability of success for the fabrication process; and
determining the feasible region based on data points of the defined design space with corresponding probability value that exceeds a feasible threshold value.

7. The computer implemented method of claim 1, wherein defined design space comprises at least one range of feasible values corresponding to at least one process parameter for the fabrication process and with at least one defined step value for the at least one range of feasible values that is used to determine data points within the defined design space.

8. The computer implemented method of claim 1, wherein after selecting one or more recommended data points, the computer implemented method further comprises:
sending instructions to a fabrication device, wherein the instructions include the one or more recommended data points and a command to execute one or more fabrication processes using the one or more recommended data points; and
wherein the experimental results corresponding to the one or more recommended data points is received from the fabrication device.

9. The computer implemented method of claim 1, wherein the fabrication process comprises chemical synthesis, 3D printing, a manufacturing process, fabrication of a device, fabrication of a nanomaterial, fabrication of a metamaterial, fabrication of a microelectronic or nanoelectronic chip, fabrication of a sensor, fabrication of a MEMS or NEMS device, fabrication of a magnetic material, synthesis of a drug, formulation of a drug, a crystallization process such as a protein crystallization process, engineering of a cell, protein, or gene, or sequencing of a nucleic acid such as sequencing of a genome.

10. The computer implemented method of claim 1, wherein the fabrication process comprises one or more of chemical vapor deposition process, a metal organic chemical vapor deposition process, a physical vapor deposition process, or atomic layer deposition process.

11. The computer implemented method of claim 10, wherein the fabrication process comprises use of chemical vapor deposition to synthesize a 2D material.

12. The computer implemented method of claim 1, wherein the process parameters include one or more of temperature, pressure, humidity, pH, concentration of one or more reactants or intermediates, presence or absence or type of a catalyst, presence or concentration of solvent, presence or type of a solid support, flow rate or composition of a gas or solution, choice or amount of a reactant or material, physical separation of reactants, or form of a component or device used in the fabrication process.

13. The computer implemented method of claim 1, wherein the classification model is trained with a training dataset comprising at least one multivariate input-output pair labeled with a feasibility value corresponding to a probability of a successful fabrication process.

14. The computer implemented method of claim 1, wherein the classification model is a semi-supervised classification model.

15. The computer implemented method of claim 1, wherein the regression model is a Gaussian Process regression model.
